(19) United States
(12) Patent Application Publication
(10) Pub. No.: US 2025/0111110 A1
(43) Pub. Date: Apr. 3, 2025

(54) METHOD TO SIMULATE EFFECT OF TURBULATOR-CENTRALIZER ON DISPLACEMENT OF WELLBORE FLUIDS WHILE CEMENTING

(71) Applicant: Halliburton Energy Services, Inc., Houston, TX (US)

(72) Inventors: Anoop Sheshrao Jogdand, Pune (IN); K V V N Krishna Babu Yerubandi, Houston, TX (US); Walmy Cuello Jimenez, Houston, TX (US)

(21) Appl. No.: 18/598,517

(22) Filed: Mar. 7, 2024

Related U.S. Application Data
(60) Provisional application No. 63/541,492, filed on Sep. 29, 2023.

(51) Int. Cl. G06F 30/28; E21B 33/14

(52) U.S. Cl. CPC G06F 30/28; E21B 33/14; E21B 2200/20

(57) ABSTRACT

Prepare a work order (WO) by: collecting user input; running an initial CFD-based cementing operation simulation, outputting a CFD result including simulated annular placement of cement with insufficient DE. Choose a section of casing; simulate mechanically coupling a turbulator to adjust displacement efficiency (DE) of cement within the annulus before casing installation; adjust turbulator mechanical properties to maximize DE; create the WO including adjusting turbulator spacing along the casing of the wellbore to one turbulator per joint; perform an additional CFD-based simulation with adjusted turbulator spacing to update and output simulated annular placement of cement and DE; determine a change in DE; adjust the WO based on a further simulation loop; and finalize the WO. Cement the wellbore by: transporting turbulators to a wellsite; installing wellbore casing spaced by turbulator spacing of the finalized WO; and pumping cement into the annulus, the cement contacting the turbulators to reduce channeling.

### CROSS-REFERENCE TO RELATED APPLICATIONS

The application claims priority to U.S. Provisional Application No. 63/541,492 filed Sep. 29, 2023, entitled “Method to Simulate Effect of Turbulator-Centralizer on Displacement of Wellbore Fluids While Cementing,” which is incorporated by reference herein in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

In the construction of oil and gas wells, a wellbore is drilled into one or more subterranean formations or zones containing oil and/or gas to be produced. In most instances, after the wellbore is drilled, the drill string is removed and a casing string including at least one joint of casing is run into the wellbore. The annular space between the wellbore wall (and thus the subterranean formation) and a casing string, generally referred to as an annulus, is fillable with cement to isolate pressure within the wellbore from pressure within the formation. This also seals the annulus to the casing, seals the formation, and prevents a wellbore cave-in. The process of filling the annulus with cement can be referred to as “cementing” the wellbore.

In many such wellbores, centralizers are installed on at least one of the joints to keep the casing string centered within the wellbore. An uncentered casing string risks introducing effects harmful to the operation of the wellbore. These include but are not limited to drag (e.g., the casing contacting the wellbore), differential sticking (e.g., the casing string contacting a portion of the permeable formation where the pressure in the wellbore is greater than the pressure in the formation and the higher pressure holds the casing string in contact with lower pressure area). More generally, uncentered casing string causes detrimental channeling during the cementing process, wherein the cement fails to flow (and thus, fails to set or fails to cure cure) uniformly between the casing string and the borehole wall, leaving portions of the annulus devoid of cement. Channeling results from differential flow, wherein the cement flows in a narrow path instead of covering an entire annulus. Centralizers ensure that cement surrounds the outside of the casing, ameliorating these effects. One type of centralizer, a turbulator, is usable both for forward cementing operations and reverse cementing operations.

However, a variety of turbulators of varying shapes and sizes and having differing mechanical properties and other performance characteristics exist. Turbulators are mechanically coupled to at least one joint of the casing string that is inserted into the wellbore before the annulus is filled with cement and that cement is allowed to cure. Non-destructively correcting errors in either the selection of the variety, or varieties of turbulator used or the number of turbulators used per each joint of the casing string, during the cementing operation is often not commercially practicable. Further, at least in part because the characteristics of each wellbore and the associated formation(s) vary widely, historical guidance is either not available or not practicably usable to reliably model, at the pre-construction stage, the impact on cement placement of (1) the geometry of a specific turbulator and (2) the spacing of each turbulator within each joint of a wellbore for either forward cementing or reverse cementing operations.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a schematic view illustrating a cementing operational environment according to an embodiment of the disclosure.

FIG. 2A is an elevational view of a casing string of a wellbore that is mechanically coupled to a plurality of turbulator-centralizers according to an embodiment of the disclosure.

FIG. 2B is a cutaway perspective view of a third casing string of a wellbore that is mechanically coupled to a first type of turbulator according to an embodiment of the disclosure.

FIG. 2C is a cutaway perspective view of a third casing string of a wellbore that is mechanically coupled to a second type of turbulator according to an embodiment of the disclosure.

FIG. 2D illustrates a side elevational view of the first type of turbulator according to an embodiment of the disclosure.

FIG. 3 is an illustration of an exemplary turbulator specification sheet according to an embodiment of the disclosure.

FIGS. 4A-4B illustrate a comparative wellbore of a well cemented without turbulators.

FIGS. 5A-5B illustrate an alternate comparative wellbore of a well cemented without turbulators.

FIGS. 6A-6D are an illustration of experimental results of a simulation of wellbore cementing operation displacement efficiency incorporating at least one turbulator according to an embodiment of the disclosure.

FIG. 7 is a process flow illustrating a three-dimensional (3D) turbulator simulation model according to an embodiment of the disclosure.

FIG. 8 is a process flow illustrating an alternative representation of a three-dimensional (3D) turbulator simulation model according to an embodiment of the disclosure.

FIG. 9 is a process flow illustrating a computational fluid dynamics (CFD)-based simulation model for determining turbulator spacing according to an embodiment of the disclosure.

FIGS. 10A-10C illustrate a user interface for inputting turbulator data and turbulator data inputs associated with a simulation of an impact of at least one turbulator on a wellbore cementing operation according to an embodiment of the disclosure.

FIG. 11 illustrates a side elevational view of a casing string mechanically coupled to a plurality of turbulators placed within an axial cell within a wellbore according to an embodiment of the disclosure.

FIGS. 12A-12G illustrate a user interface and output of a CFD-based simulation model of turbulator spacing for a wellbore reverse cementing job according to an embodiment of the disclosure.

FIGS. 13A-13B illustrate a PBL plot and a CPF plot associated with the CFD-based simulation model of turbulator spacing for a wellbore reverse cementing job of FIGS. 12A-12H according to an embodiment of the disclosure.

FIGS. 14A-14G illustrate a user interface and output of a CFD-based simulation model of turbulator spacing for a first wellbore forward cementing job according to an embodiment of the disclosure.

FIGS. 15A and 15B illustrate PBL and CPF plots associated with the CFD-based simulation model of turbulator spacing for the first wellbore forward cementing job of FIGS. 14A-14G according to an embodiment of the disclosure.

FIGS. 16A-16G illustrate a user interface and output of a CFD-based simulation model of turbulator spacing for a second wellbore forward cementing job according to an embodiment of the disclosure.

FIGS. 17A-17B illustrate a PBL plot and a CPF plot associated with the CFD-based simulation model of turbulator spacing for the second wellbore forward cementing job of FIGS. 16A-16G.

FIG. 18 illustrates a block diagram of a system for performing a wellbore cementing operation on a wellbore according to an embodiment of the disclosure.

FIG. 19 is a flow chart of a wellbore servicing method according to an embodiment of the disclosure.

FIG. 20 is a block diagram of a system for using a three-dimensional (3D) computational fluid dynamics (CFD)-based model to prepare a finalized work order associated with a wellbore cementing operation in a planning phase and to schedule the wellbore cementing operation based on the finalized work order according to an embodiment of the disclosure.

FIG. 21 is a block diagram illustrating a computer system according to an embodiment of the disclosure and suitable for implementing one or more embodiments of the disclosure.

### DETAILED DESCRIPTION OF THE INVENTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The present disclosure is generally directed to a cementing operational environments used in oilfield servicing operations to perform wellbore cementing, and specifically directed to systems and methods to utilize a computational fluid dynamics (CFD)-based model to (1) simulate and quantify the impact of at least one turbulator on displacement efficiency (DE) of wellbore fluids (e.g., cement or cement slurry) while cementing; and (2) based on a CFD simulation, choose a turbulator size and spacing that achieves a desired DE. In some embodiments, DE expressed as a percentage and defined by the following ratio, where cᵢ represents the concentration of the displacing fluid, aⱼ represents the area of each cell, the cell (also referred to as an “axial cell” herein) being a unit in which the wellbore cross-section is divided, and Aₐₙₙᵤₗᵤₛ represents the cross-section area of the annulus:

$$DE ( \% ) == \frac{area of displacing fluid in annulus}{cross section of annulus} = \frac{\sum ( {c}_{i} \cdot {a}_{j} )}{{A}_{annulus}}$$

In embodiments, the DE ratio quantifies the fraction of the wellbore annular cross-section occupied by the displacing fluid. In such embodiments where cement is the displacing fluid, the DE is equivalent to the concentration of cement at a given wellbore cross-section, which changes with time and space during the displacement process. This cement concentration is determinable using CFD according to the systems and methods herein.

The DE in wellbore cementing refers to how effectively drilling mud or other fluids are displaced from the wellbore by the cement or cement slurry during the cementing operation. A higher DE indicates that there is inversely proportional less contamination of the cement by drilling mud or other fluids. Such contamination contributes to a weak bond between the cement and the casing or formation (e.g., by causing channeling). Achieving a high DE is indicative of the cement slurry effectively displacing as much of the drilling mud as is practicable.

In some examples where the DE is insufficient for a particular wellbore and a particular cementing operation, the casing becomes off-center relative to the wellbore during the cementing operation. In some such examples, at least a portion of the casing contacts the annulus at least in part because fluid flow is greater on the opposite side, away from the contact point. This has numerous deleterious effects on the cementing operation and the wellbore, as discussed elsewhere herein. Also as explained elsewhere the presence of at least one turbulator in a casing joint assists in rotating fluid as that fluid is passing through the turbulator, which enhances fluid placement and assists in keeping the casing centered in the wellbore.

Typically, the design of an oil well comprises at least two strings of casing cemented into place to secure the wellhead and provide zonal isolation. A first string of casing can be a relatively short string (referred to as surface casing) to secure the wellhead and to prevent loss of drilling fluids to surface aquafers. A second string of casing can be a longer string (referred to as production casing) that penetrates the formation and provides an isolation barrier to prevent formation fluids from contacting the casing. Although only two casting strings are described, an oil and gas well can comprise more than two and indeed any number of casing strings.

A successful cementing operation begins with a design of the cementing operation that comprises a cement slurry, a pumping procedure, and various downhole tools, e.g., float shoe. The cementitious slurry generally comprises a blend of cement material (typically Portland cement), a liquid (typically water), and various chemicals to tailor the cement slurry for the downhole environment and/or the pumping operation. For example, a retarder or accelerator can be added to the cement slurry to slow down or speed up the curing process. A pumping procedure can be a set of instructions to mix and deliver a fluid treatment, e.g., cement slurry, into a wellbore. The pumping procedure can include time-based or volume-based intervals comprising pumping pressures, pumping flowrates, pump volumes, cement blends, and chemical additives to pump a cement slurry into the wellbore via a set of pumping equipment. The cementing operation may utilize various specialized downhole equipment such as wipers, darts, float shoes, and casing centralizers to enhance the quality of the cement bond. In some implementations, at least one casing centralizer is used to ensure that a casing is properly centered within the borehole.

The disclosed systems and methods enable constructing a casing string made up of at least one joint centered within a wellbore while using the smallest number of effective turbulators per each joint (or, in the alternative, per each section as “section” is defined herein). The smallest number of effective turbulators per joint is determined by utilizing a turbulator model to (1) simulate and quantify the impact of at least one turbulator on DE of wellbore fluids while cementing; and based on the DE derived from the turbulator model simulation, (2) utilizing a CFD-based model to choose a turbulator size and spacing within each joint that achieves a desired DE throughout the joint and the casing string.

By enabling a cementing job wherein a casing string remains centered within a wellbore through the use of turbulators, the disclosed systems and methods reduce effects harmful to the operation of the wellbore after cementing operations are completed, including drag, differential sticking, and channeling. The disclosed systems and methods thus ensure that following wellbore cementing operations, the cement surrounds the outside of the casing, fills the annulus as intended, and enables reduced or eliminated channeling.

The disclosed systems and methods operate unconventionally at least by using the output of the turbulator model as input for the CFD-based model before a cementing operation at a wellbore to quantify the impact of at least one turbulator on the DE of wellbore fluids while cementing. Also, based on the DE derived from the turbulator simulation, the CFD-based model indicates an efficacy of a turbulator size and spacing within each joint that achieves a desired DE throughout the joint and the casing string. The CFD-based model is operable with any size of turbulator. In some embodiments, a user selects a turbulator size to be simulated prior to simulation via the CFD-based model. In some such embodiments, the CFD-based model enables the user to simulate a turbulator having a size, as measured by a nominal diameter, as close as practicable to the open hole diameter of the wellbore. Utilizing a turbulator having a nominal diameter as close as practicable to the open hole diameter of the wellbore reduces an amount of fluid (e.g., cement) that potentially bypasses the turbulator vanes, enhancing the efficiency of the turbulator to impart swirl. Thus, such embodiments of the CFD-based model enable testing, via simulation, various sizes of the turbulator to achieve the most efficient practicable swirl for a specific wellbore servicing operation. Thus, simulation(s) using the CFD-based model enable avoiding errors or other suboptimal results related to either the selection of the variety, or varieties of turbulator used or the number of turbulators used per each joint of the casing string during cementing operations. Additionally, using the CFD-based model also enables the user to tailor simulations to turbulators which are actually available for use in a specific wellbore servicing operation.

Thus, there is little or no need to alter the variety, or varieties of turbulator used or the number of turbulators used per each joint of the casing string after completion of the cementing operation and setting or curing of the cement. Further, the disclosed systems and methods are based on a microscopic model. The disclosed microscopic model is applicable to both forward cementing and reverse cementing operations as discussed elsewhere herein. Additionally, the disclosed microscopic model not restricted to use with only straight wells, but is usable with types of wellbores including but not limited to: inclined wellbores, deviated wellbores, and extended reach drilling (ERD) wellbores. The disclosed microscopic model is thus adaptable to use with a variety of types of wellbore, in contrast to contemporary known empirical approaches which fail to account for the varying characteristics of each type of wellbore and thus deliver less accurate results.

Thus, unlike in an empirical model, no historical data on previous cementing operations having a wellbore or formation(s) with similar characteristics is required. As such historical data tends not to exist for most wellbores presently under construction, the disclosed systems and methods are thus more readily usable in more actual, real-world wellbore cementing jobs than contemporary, pre-existing empirical approaches.

The disclosed systems and methods include a full three-dimensional (3D) simulation, via a CFD-based model, of any turbulator, including those commercially available before, at the time of, or after this disclosure (referred to herein as a “turbulator simulation”). While embodiments are discussed in detail herein with reference to a 3D CFD model, any other suitable CFD model may be employed including 2D or other legacy/convention CFD model types. The turbulator simulation includes a determination of the cement DE of the turbulator within an annulus. The DE is represented in some embodiments as a percentage of the annular volume (or, volume of an annulus) that is occupied by cement. Some embodiments of the turbulator simulation are configured to complement existing 3D displacement simulators for well cementing operations, enabling selection of a specific turbulator size and a spacing between the turbulators of the selected size to achieve a target DE. Depending on the needs of the implementation, the turbulator simulation is operable to study wellbore geometry for any circulation pattern (e.g., forward cementing, reverse cementing, etc.).

The turbulator simulation enables proposing and testing the use of turbulators in real-world well cementing operations while the well cementing operations are still in the planning stage. Thus, the efficacy of the usage of turbulators in a real-world cementing operation is determinable before a specific cementing job begins, based on a microscopic physics-based turbulator simulation. This enables quantifying the mechanical benefits (e.g., how well the turbulator will function as a centralizer within a specific wellbore environment) of using specific turbulators in specific, real-world actual well cementing jobs before such jobs begin. In some embodiments, based on such quantification, jobs are either enabled to proceed as planned, or modified to achieve desired results. Such modifications include, e.g., selecting a different type or size of turbulator. The proposed modifications are readily testable by the turbulator simulation, thus allowing repeated changes in the turbulator type and size until desired results are achieved in the turbulator simulation, which culminates in overall enhancement of the entire cementing job design at the job planning stage.

The turbulator simulation additionally captures the swirl effect generated by a turbulator-type centralizer within a wellbore annulus during, wellbore servicing operations (e.g., cementing operations), and quantifies the impact of the swirl effect on the displacement of annular fluids (e.g., cement). In embodiments herein, the swirl effect is quantified by a swirl number(S). In such embodiments, the swirl number quantifies a degree of swirl imparted on the annular fluids. S is a nondimensional number representing a ratio: an axial flux of swirl momentum divided by the axial flux of axial momentum.

In the analysis of swirl flow, there are a number of formulae for deriving S based on what types of data are available. Without limitation on which data is available in implementations of the systems and methods disclosed herein, a first formula usable to compute S (the “first S formula”) is:

$$S = \frac{2}{3} [ \frac{1 - {( \frac{{d}_{h}}{d} )}^{3}}{1 - {( \frac{{d}_{h}}{d} )}^{2}} ] tan Φ$$

In the context of a turbulator, the first S formula, d and dₕ are nozzle (inner) and vane pack (outer) hub diameters of the turbulator, respectively. The angle phi (Φ), measured in degrees, is the swirl vane angle (i.e., the inclination of the vanes with respect to the center axis), also called the exit angle, of the turbulator. In embodiments, this is the angle at which fluids leave the vanes.

In some embodiments, a turbulator is hubless, or dₕ/d is otherwise so small as to approach zero. In such embodiments, the first S formula is reducible to a second S formula. The second S formula is:

$$S = \frac{2}{3} tan Φ$$

For example, when computing S for turbulators for which the second S formula is usable, exemplar turbulator vane angle and S pairs include but are not limited to: [(15°, 0.2); (30°, 0.4); (45°, 0.7); (60°, 1.2); (70°, 2.0); (80°, 4.0)]. While the second S formula is more efficient for specific turbulators, the first S formula is usable with all turbulators. All embodiments, systems, and methods disclosed herein are understood to use whichever of the first S formula or the second S formula provides a correct calculation of S for a given turbulator.

As noted above, in embodiments herein, the swirl number S quantifies a degree of swirl imparted on the annular fluids by a turbulator as a nondimensional number representing the ratio of an axial flux of swirl momentum divided by the axial flux of axial momentum. The first S formula and the second S formula are thus expressed based on the geometry of the turbulator. However, the degree of swirl imparted on the annular fluids is quantifiable in other ways. For example, in addition to the foregoing, S is also expressible as the ratio of the tangential velocity V_{θ} to the axial velocity Vₐₓᵢₐₗ at any given point. This ratio is the basis of a third S formula. Embodiments using the third S formula first estimate S from either the first S formula or the second S formula, and then use the estimated S number to determine a tangential velocity Ve. The Vₐₓᵢₐₗ is the average velocity of flow in the annulus based on a known flow rate.

The third S formula, usable to determine the tangential velocity V_{θ} as described above, is:

$$S = \frac{{V}_{θ}}{{V}_{axial}}$$

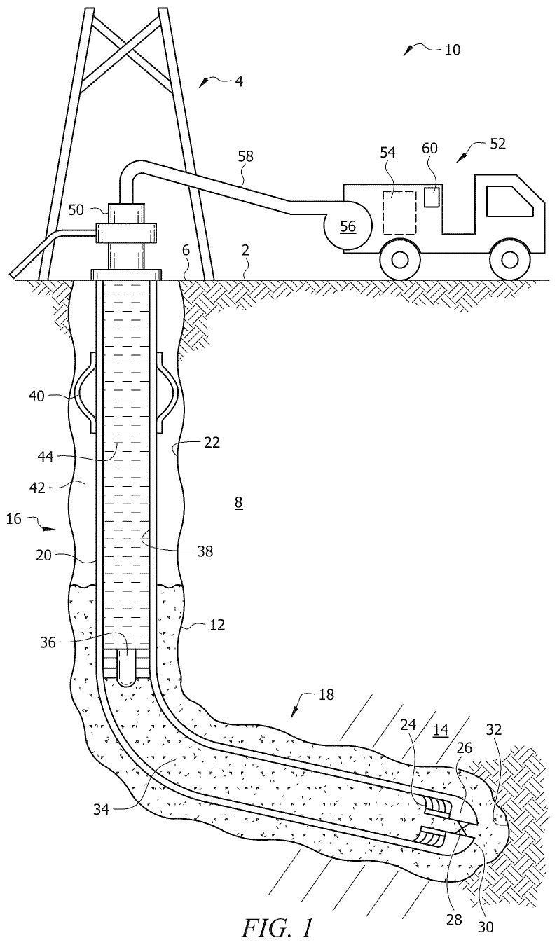

Turning now to FIG. 1, an embodiment of a cementing operating environment is illustrated. The cementing operating environment 10 comprises a servicing rig 4 that extends over and around a wellbore 12 that penetrates a subterranean formation 14 for the purpose of recovering hydrocarbons. A casing string 20 can be conveyed into the wellbore 12 by the servicing rig 4 or any other type of drilling rig such as a workover rig, an offshore rig, or similar structure. A wellhead 50 may be coupled to the casing string 20 at surface 2. A pump unit 52, located offshore or on land, can be fluidically coupled to a wellhead 50 by a supply line 58. The wellbore 12 can extend in a substantially vertical direction away from the earth's surface 2 and can be generally cylindrical in shape with an inner bore 22. At some point in the wellbore 12, the vertical portion 16 of the wellbore 12 can transition into a substantially horizontal portion 18. The wellbore 12 can be drilled through the subterranean formation 8 to a hydrocarbon bearing formation 14. Perforations made during the completion process that penetrate the casing 20 and subterranean formation 14 can enable the fluid in the subterranean formation 14 to enter the casing 20.

In some embodiments, a cementing operation can include a pump unit, a cement blend, a pumping procedure, and a variety of chemicals. The pump unit 52, also called a cementing unit, comprises a mixing system 54, a pumping mechanism 56, and a unit controller 60. The unit controller 60 may be a computer system suitable for communication with the service personnel and control of the mixing system 54 and the pumping mechanism 56. The mixing system 54 can mix the cement blend with a liquid, e.g., water, to form a cement slurry 34. The pumping mechanism 56 can deliver the cement slurry 34 from the mixing system 54 to the wellbore 12 via the supply line 58.

In some embodiments, the wellbore 12 can be completed with a cementing process that follows a cementing pumping procedure to place a cement slurry 34 between the casing string 20 and the wellbore 12. The wellhead 50 can be any type of pressure containment equipment connected to the top of the casing string 20, such as a surface tree, production tree, subsea tree, lubricator connector, blowout preventer, or combination thereof. The wellhead 50 can include one or more valves to direct the fluid flow from the wellbore and one or more sensors that measure pressure, temperature, and/or flowrate data. The pump unit 52 can follow a pumping procedure with multiple sequential steps to mix a cement blend with water to form a cement slurry 34 and place the cement slurry 34 into the annular space 42. The pumping procedure can include steps of pumping a spacer fluid to separate the drilling fluid, e.g., drilling mud, from the cement slurry 34. The pumping procedure can include instruction for downhole tools, for example, releasing and pumping a first cementing wiper plug 24, also called a lower plug, to physically separate the spacer fluid (or other wellbore fluids) from the cement slurry 34. The wiper plug 24 comprises a plurality of flexible fins, or wipers, that sealingly engage the inner surface 38 of the casing 20 with a sliding fit. The pump unit 52 can pump a predetermined volume of cement slurry 34 though the supply line 58, the wellhead 50, and into the casing string 20. A second cementing wiper plug 36, also called an upper plug, can be released from surface following the predetermined volume of cement slurry. A volume of spacer fluid 44 or other type of completion fluid can be pumped after the cementing wiper plug 36 (the upper plug) to displace the cementing wiper plug 36 down the casing string 20. In some embodiments, the volume of cement slurry 34 located between the upper plug 36 and lower plug 24 can be pumped through the lower plug 24 after the lower plug 24 contacts the float shoe 26 and a shear disk or rupture disk is broken. The upper plug 36 can push the cement slurry 34 through the lower plug 24, out the float shoe 26 (or other suitable primary cementing equipment), and into the annular space 42 between the casing string 20 and the wellbore 12.

In some embodiments, various downhole equipment can be included in the pumping procedure, for example, a plurality of centralizers 40 can be coupled to the casing string 20 to maintain the annular gap within the annular space 42 between the casing string 20 and the wellbore 12. In some embodiments, at least one centralizer is a turbulator centralizer (also referred to simply as a “turbulator” herein). In still other embodiments, however, the primary cementing equipment, e.g., float shoe 26, at the end of the casing string 20 can be drilled out and a liner can be added to extend the length of the wellbore 12.

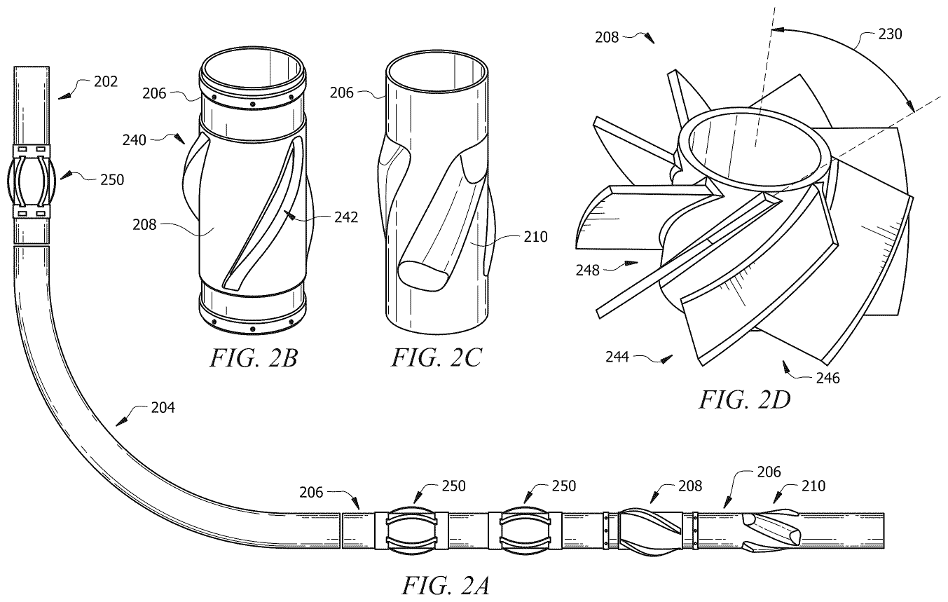

Turning now to FIGS. 2A-2D, hypothetical turbulators within a cementing operational environment, usable with the systems and methods disclosed herein, are described according to an embodiment of the disclosure.

FIG. 2A illustrates an elevational view of a casing string 200 of a wellbore that is mechanically coupled to a plurality of turbulator-centralizers according to an embodiment of the disclosure. The casing string 200 includes a first joint of casing 202, a second joint of casing 204, and a third joint of casing 206. The casing string 200 is mechanically coupled to at least one of a first type of turbulator 208 and at least one of a second type of turbulator 210. The casing string 200 may also include one or more traditional centralizers 250 mechanically coupled to one or more of the first joint of casing 202, the second joint of casing 204, or the third joint of casing 206, for example a bow-spring centralizer.

FIG. 2B illustrates a cutaway perspective view of the third casing string 206 of a wellbore that is mechanically coupled to the first type of turbulator 208 according to an embodiment of the disclosure. FIG. 2C illustrates a cutaway perspective view of the third casing string 206 of a wellbore that is mechanically coupled to the second type of turbulator 210 according to an embodiment of the disclosure.

FIG. 2D illustrates a side elevational view of the first type of turbulator 208 according to an embodiment of the disclosure. The first type of turbulator 208 of FIG. 2D is also referred to in some embodiments as a “flat-vane axial swirl generator.” The first type of turbulator 208 features a blade exit angle theta (θ) 230. In some embodiments, these measurements are usable as input into the first S number formula described above, herein. In embodiments herein, a rigid vane solid body turbulator (e.g., the first type of turbulator 208, as shown FIG. 2B and in detail in FIG. 2D) is enhances the mixing and flow of cement or cement slurry inside a wellbore during cementing operations. This device is designed to improve the distribution of cement between the casing and the formation (that is, within the annulus), to facilitate a successful and durable well completion. The primary components of a rigid vane solid body turbulator (suitable for forward cementing operations or reverse cementing operations) include:
Main body 240: A structure (including but not limited to a tubular structure) that is mechanically coupled to the casing string. The main body 240 is a support structure for the other components of the rigid vane solid body turbulator and provides a conduit for the cement slurry to flow through.
Vane Structure 242: The vane structure 242 consists of at least one rigid vane 244 or blade 244 (unless noted otherwise, “vane” and “blade” are used interchangeably throughout this disclosure) that are attached to the main body 242 at regular intervals. Each vane 244 is positioned to disrupt the flow of the cement as it travels through the wellbore. The vanes 244 create turbulence and eddies in the cement. The turbulence and eddies promote better mixing and prevent or reduce channeling. In embodiments where concrete is present as part of the cement slurry, segregation of the concrete is also prevented or reduced.
Blade orientation 246: Blade orientation 246 is determinative of the effectiveness of the blade 244. Typically, the blades 244 of the vane structure 242 are set at an angle to the axis of the main body 240, ensuring that the cement slurry is forced to change direction multiple times as it flows past the rigid vane solid body turbulator. This repeated change in direction facilitates breaking up any potential laminar flow and encourages thorough mixing of the cement.
Vane Spacing 248: The spacing between the vanes 244 is designed to a specific amount of turbulence and mixing. In embodiments, the specific vane spacing 248 varies depending on the wellbore geometry, cement properties, and other factors. Selecting a best fit vane spacing 248 to match the properties of a wellbore contributes to achieving a desired cement distribution or DE.
Material: In some embodiments, rigid vane solid body turbulators are constructed from materials that are chosen based on having mechanical properties enabling surviving and functioning correctly within a wellbore environment. Such materials include but are not limited to steel or non-corrosive alloys. Such materials ensure that the turbulator remains structurally sound and effective during the cementing process.
Attachment Mechanism: The rigid vane solid body turbulator is securely mechanically coupled to the casing string at the desired depth within the wellbore. In some embodiments, various attachment mechanisms, including but not limited to threaded connections or specialized downhole tools, are usable to ensure that the turbulator stays in place during cementing operations.
Flow Ports: In some embodiments, the main body 240 of the rigid vane solid body turbulator includes flow ports or windows. These allow the cement to flow through the turbulator while the vanes impact the flow of the cement as described elsewhere herein.

In embodiments herein, proper selection and placement of rigid vane solid body turbulators help to prevent issues including but not limited to channeling, gas migration, and incomplete zonal isolation.

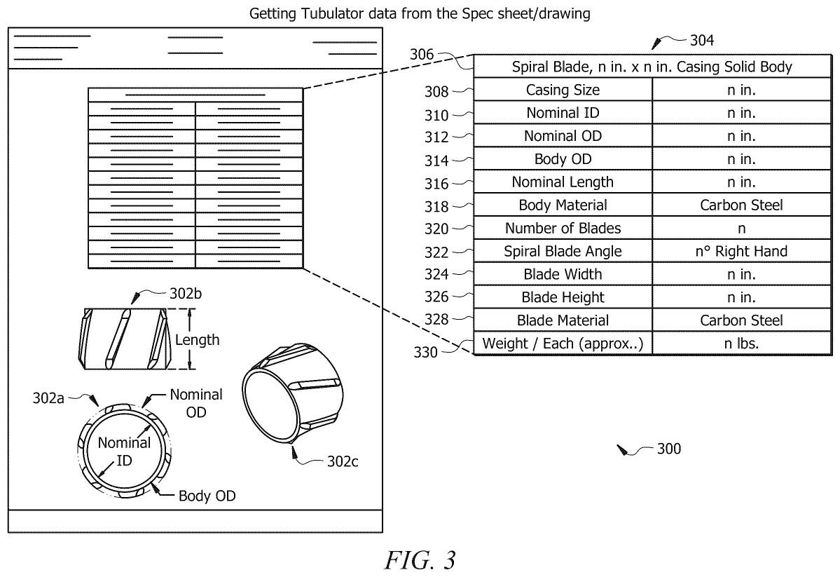

Turning now to FIG. 3, a turbulator specification sheet 300 according to an embodiment of the disclosure is illustrated. The turbulator specification sheet 300 is a non-limiting example providing hypothetical turbulator data 304 (also “turbulator data 304” herein) on a hypothetical turbulator 302. Multiple views of the hypothetical turbulator 302 are depicted, including plan view 302a, side elevational view 302b, and perspective view 302c.

The hypothetical turbulator 302 is shown and discussed herein only to illustrate a non-limiting example of the turbulator data 304 available in some such real-world turbulator specifications. These include a turbulator general description 306. In some embodiments, the turbulator general description 306 provides the product name and high-level information used to classify the hypothetical turbulator 302. In this example, the hypothetical turbulator 302 is a “Spiral Blade, 9-⅞″×12 Casing Solid Body” turbulator. Thus, the blade topology and a compatible wellbore casing are identified. Other specifications of the hypothetical turbulator 302 include but are not limited to:

| Casing size 308 (here, the same as the casing size | |
|---|---|
| listed in the turbulator general description 306) | Body material 308 |
| Nominal inner (or internal) diameter (ID) 300 | Number of blades 300 |
| Nominal outer diameter (OD) 302 | Spiral blade angle 302 |
| Body outer diameter (OD) 304 | Blade width 304 |
| Nominal length 316 | Blade height 306 |
| Body material 308 | Blade material 308 |

Weight per turbulator 300

In embodiments herein, the nominal length 316 is the length of the hypothetical turbulator 302 measured end to end.

No restriction is made, nor is any restriction intended to be made, on the kinds of data available in turbulator specifications or how that data is presented, except as stated otherwise herein. In some embodiments, some data present on specification sheet 300 will not be present in the listed specifications for a specific real-world turbulator, and if that data is needed it will need to be derived from direct measurements, other available data in the real-world listed specifications, or from other applicable sources.

Before examining in further detail the positive impact that turbulators have on DE during well cementing operations, examining a cementing operation wherein turbulators are not used provides a useful frame of reference.

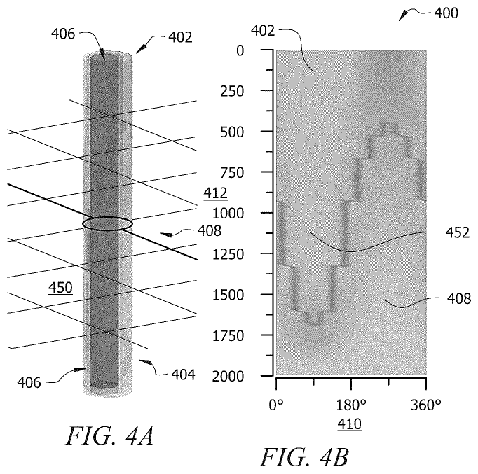

Turning now to FIGS. 4A-4B, a wellbore 400 of a well cemented without turbulators according to an embodiment of the disclosure is illustrated. FIG. 4A illustrates the wellbore 400 from an external point of view and with the surrounding formation rendered transparent. An annulus 402 is rendered as translucent to facilitate examining interior elements of the wellbore. FIG. 4B illustrates a closeup view of cement placement within the annulus 402. In FIG. 4B, the annulus 402 is presented as unrolled to facilitate ease of reference in the following discussion. A casing string 450 is off-center within the annulus 402, leaving a wide side 404 and a narrow side 406 within the annulus. This lack of centralization of the casing string is detrimental to cementing operations for the reasons previously discussed herein and shown by the placement of a cement 408. In FIG. 4A, the placement of the cement 408 is starkly uneven across the annulus 402, with a greater mass of the cement 408 having concentrated on the wide side 404 than on the narrow side 406.

This suggests the presence of at least a considerable amount of channeling, which is illustrated in FIG. 4B. FIG. 4B illustrates the state of the annulus 402 and the cement 408, viewed as if the annulus 402 were sliced open and unrolled to lie flat. A legend 410 maps each location on the flattened annulus 402 to the same location on the tubular annulus 402, at various depths 412. As presented in FIG. 4B, severe, detrimental channeling of the cement 408 is readily apparent, and the poor effective DE of the turbulator-free cementing operation is clearly demonstrated.

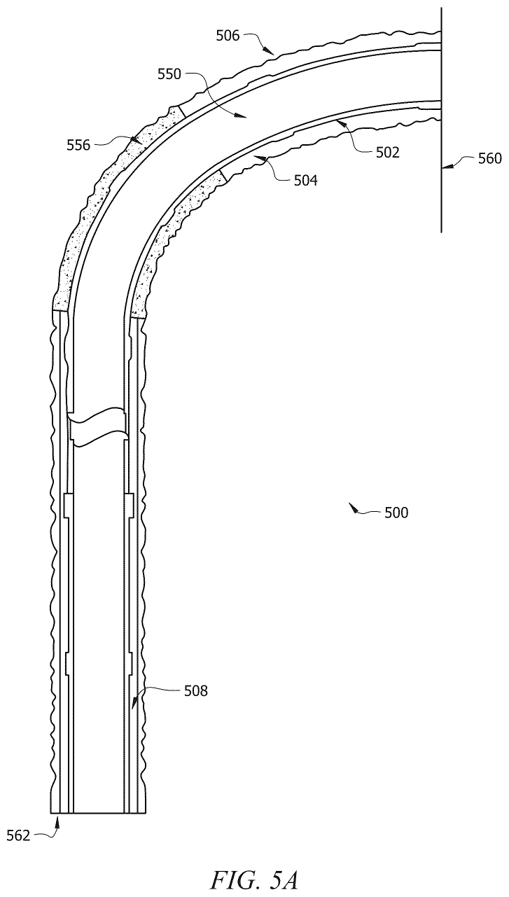

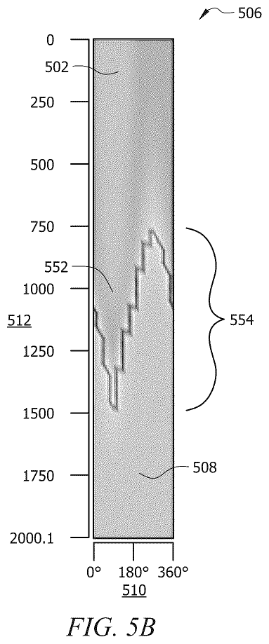

Turning now to FIGS. 5A-5B, an alternate comparative wellbore 500 of a well cemented without turbulators is illustrated according to an embodiment of the disclosure. The wellbore 500 is an example of the type of wellbore created using extended reach drilling (ERD) techniques. Wells created using ERD techniques are suitable for particularly long horizontal wells. In some embodiments, ERD enables drilling and cementing horizontal wells wherein the ratio of a measured depth (MD) to a true vertical depth (TVD) is at least two-to-one. In the example of wellbore 500, a forward cementing job is used. A surface 560 depicted in FIG. 5A is above ground, and is the point from which drilling begins.

In comparison to the wellbore 400 of FIGS. 4A-4B, the wellbore 500 curves into a horizontal orientation as a casing string 550 descends from the surface 560. Annulus 502, a wide side 504, a narrow side 506, a cement 508, a legend 510, and depths 512 are substantially the same in description and behavior as the annulus 402, the wide side 404, the narrow side 406, the cement 408, and the legend 410, and the depths 412. The channeling 552 exhibited by the cement 508 is substantially the same as the channeling 452 exhibited by cement 408. To this extent, the description of FIGS. 4A-4B above is applicable to FIGS. 5A-5B, and these elements will not be discussed further.

Additionally, a drilling mud 556 is present within the annulus 502, positioned above the cement 508 and closer to the surface 560. This indicates that the wellbore 500 is undergoing a reverse cementing operation, wherein the cement 508 is pumped into the annulus 502 so as to rise from a bottom 562 of the annulus 502 to the surface 560, displacing (and in some cases expelling) the drilling mud 556 as the cement 508 is pumped into place within the annulus 502. As explained elsewhere herein, turbulators are of particular use in reducing or eliminating channeling (e.g., the channeling 552). In the example of FIG. 5B, the channeling 552 covers a segment 554 from seven-hundred-and-fifty feet to fifteen-hundred feet. As shown in FIG. 5B, in some embodiments, at least one turbulator placed within a section (e.g., a joint) of the casing string 550 addresses the channeling according to the systems and methods disclosed and described elsewhere herein.

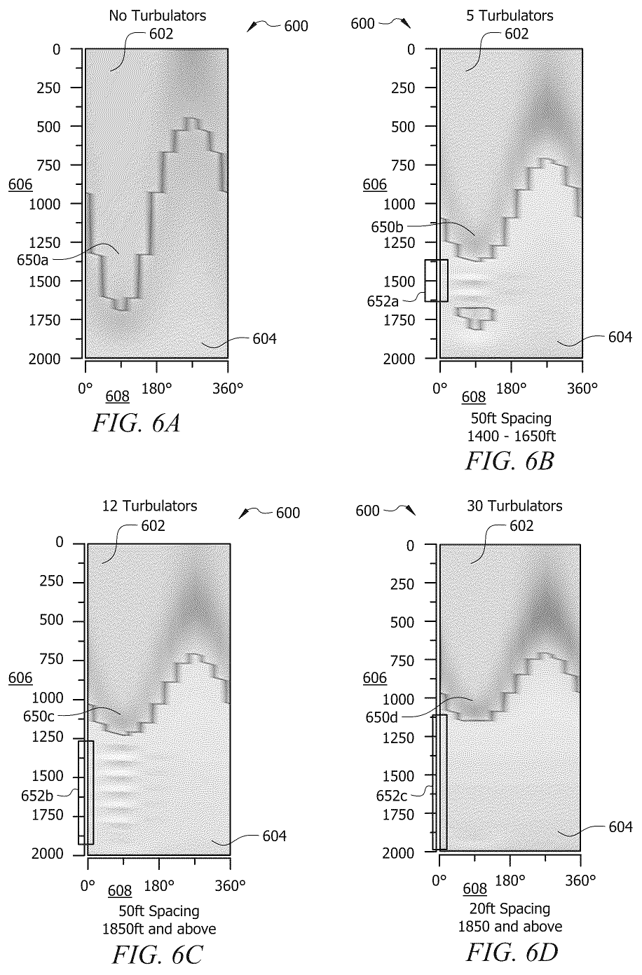

Turning now to FIGS. 6A-6D, experimental results of a simulation 600 of wellbore cementing operation displacement efficiency incorporating at least one turbulator are illustrated according to an embodiment of the disclosure. FIGS. 6A-6D are alternatively each referred to herein as the “simulation results 600.” In some embodiments, the simulation results 600 are the output of the systems and methods claimed herein for CFD-based modelling of fluid (e.g., cement) distribution, depicting the annulus of a wellbore as unrolled. In some such embodiments, the simulation 600 of FIGS. 6A-6D is conducted on the wellbore 400 of FIGS. 4A and 4B, demonstrating the impact of adding turbulators as indicated.

FIG. 6A depicts the simulation results 600 when no turbulators are present. FIG. 6A illustrates the state of an annulus 602 and a cement 604, viewed as if the annulus 602 were sliced open and unrolled to lie flat. A legend 608 maps each location on the flattened annulus 602 to the same location on the annulus 602 if the annulus 602 were in a rolled up, cylindrical configuration, at various depths 606. As presented in FIG. 6A, severe, detrimental channeling 650a of the cement 604 is readily apparent, and the poor effective DE of the turbulator-free cementing operation being simulated is clearly demonstrated.

FIG. 6B depicts the simulation results 600 wherein everything is the same as FIG. 6A except that five turbulators are present at a location 652a at the depth 606 of 1400-1650 feet, spaced fifty feet apart. While channeling 650b is still present, the channeling 650b is measurably reduced compared to the channeling 650a. FIG. 6C depicts the simulation results 600 wherein everything is the same as FIG. 6A except that twelve turbulators are present at a location 652b at the depth 606 of 1250-1850 feet, spaced fifty feet apart. While channeling 650c is still present, the channeling 650c is measurably reduced compared to the channeling 650a and 650b. FIG. 6D depicts the simulation results 600 wherein everything is the same as FIG. 6A except that thirty turbulators are present at a location 652c at the depth 606 of 1125-1850 feet, spaced twenty feet apart. Channeling 650d below the boundary of the annulus 602 and the cement 604 is effectively eliminated. In embodiments, the curvature of the boundary between the annulus 602 and the cement 604 is acceptable for a cementing operation.

The pumping procedure of the cementing operation can be determined by a design process that utilizes a turbulator displacement simulator, also referred to as a turbulator design simulator or the turbulator simulator.

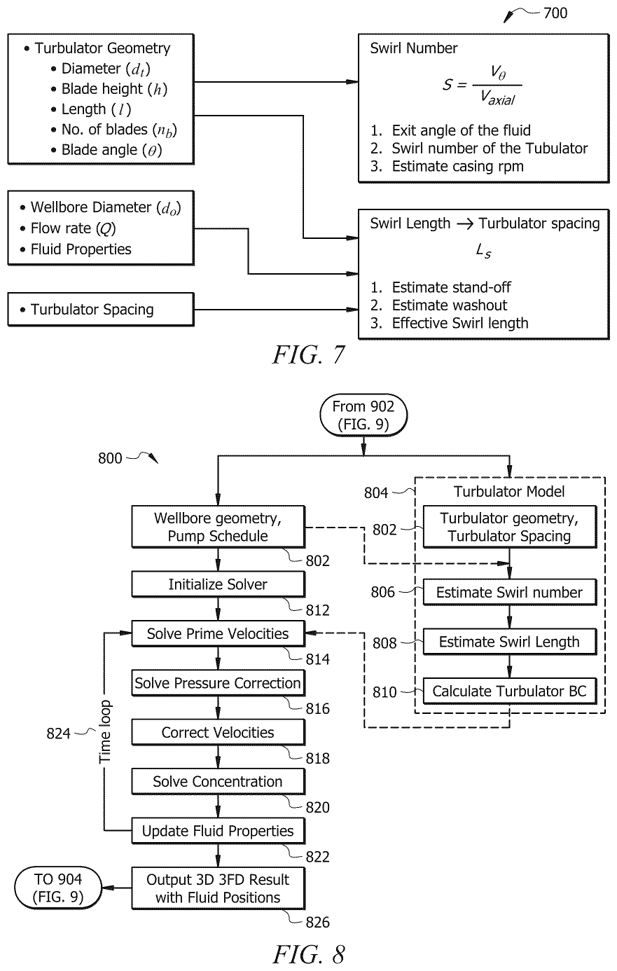

Turning now to FIG. 7, a process flow 700 for three-dimensional (3D) turbulator simulation model according to an embodiment of the disclosure is illustrated. At an operation 702, an effect of the turbulator on a DE in an annulus is captured based on collecting user inputs. These user inputs include: turbulator details (e.g., including but not limited to: type of the turbulator (e.g., rigid vane, strap on, etc.); geometry of the turbulator (e.g., including but not limited to: number of vanes, vane angle, outer and hub diameters, blade height, blade chord height); turbulator spacing; and the section (e.g., a specific joint or joints at a specific depth or depths) of the wellbore where the turbulator is placed. The user inputs further include at least: wellbore geometry; annular stand-off; circulation method; fluid pump schedule; flow rates; and fluid properties. At an operation 704, the turbulator model utilizes the user inputs to generate at least one equivalent boundary condition (BC) for a 3D CFD model. In embodiments herein, equivalent boundary conditions include but are not limited to boundary conditions created via a technique to generate the swirl effect from at least one turbulator in the annulus, in an indirect way indirectly by applying a casing rotation to the model. In such embodiments, the 3D CFD model simulates the casing rotation that during a real-world cementing operation. This simulation of the casing rotation is utilized by the turbulator model at least through identifying a section of the casing around the turbulator, and then applying a rotation (e.g., at N RPM) to the casing. The tangential velocity, as defined and discussed elsewhere herein, is then utilized to estimate the casing RPM using the following equation:

$${V}_{θ} = {r}_{casing} \cdot ω , where ω = \frac{2 π N}{60}$$

The 3D CFD model is configured to capture a swirl effect generated by the turbulator using a first factor and a second factor. At an operation 706, the first factor, a swirl number, is computed using at least one of the first S formula or the second S formula depending on the available data inputs. In some embodiments, the swirl number is calculated at least partly based on the blade exit angle (ϕ). The blade exit angle is obtained from performance curves based on turbulator vane geometry. In some embodiments, the swirl number is then calculated using the first S formula or the second S formula.

At operation 708, the second factor, a swirl length, is estimated based on the flow Reynolds number. At operation 710, using the second factor, the swirl number is modified to average out the effects of the turbulator on an entire CFD cell. In embodiments herein, while applying the CFD-based model in the process flow 700, the annular geometry being used in the simulation is discretized into small cells. The cells exist in the axial, circumferential and radial directions. “Cell” as used herein thus refers to one such cell.

At operation 712, the modified swirl number is used to estimate the azimuthal velocity imparted by the turbulator vanes based on the third S formula. At operation 714, the azimuthal velocity is applied to the casing as a fraction of the turbulator length, generating the swirl using an equivalent effect of casing rotation (or, an “equivalent RPM”). At operation 716, the casing rotation is input as a boundary condition to the 3D CFD model.

At operation 718, the 3D CFD model quantifies a fluid DE by first receiving a turbulator boundary condition on all the locations where the user has chosen to place the turbulator, and at operation 720 simulating a distribution of fluids in an annulus. Notably, since the CFD model is microscopic and applicable to any combination of any form of wellbore and circulation method, fluid DE is quantifiable in when utilizing turbulators for cementing operations in vertical, deviated, or ERD wellbores; and also when utilizing any circulation direction (e.g., forward or reverse cementing).

Turning now to FIG. 8, a process flow 800 (also called the “simulation 800”) for simulating an alternative representation of a three-dimensional (3D) turbulator simulation model according to an embodiment of the disclosure is illustrated. The process flow 800 utilizes a projection method as explained below. At operation 802, a user defines a wellbore geometry and supplies a pump schedule, a turbulator spacing, and a turbulator geometry to be tested. At operation 804, the turbulator geometry and spacing inputs are stored. The stored turbulator geometry and the spacing inputs are used to estimate a swirl number at operation 806, estimate a swirl length at operation 808, and calculate a corresponding BC to be applied in a momentum solution (e.g., a calculation of displacement efficiency) at operation 810. The BC is represented as an equivalent casing rotation for a section of the casing where the turbulator is placed. Thus, the simulation 800 determines a BC for every location inside an annulus of a wellbore where a user is investigating placing a turbulator.

In some embodiments, the flow of fluids in the wellbore is governed by the transient, incompressible Navier-Stokes equations, which represent transport of momentum in the annulus. Wellbore fluids are then tracked by solving an advection diffusion (AD) equation, which is informed by the flow field generated from solution(s) to the Navier-Stokes equations. Thus, embodiments of the simulation 800 perform at least the steps of: solving the Navier-Stokes equations, solving for the wellbore fluid concentration(s) by using at least the AD equation, and based at least in part on these solutions, determining the DE of the fluids (e.g., cement) using the DE equation presented and discussed above, herein.

At operation 812, a solver is initialized. At operation 814, the solver solves prime velocities. In embodiments herein, prime velocities are associated with transient solutions of the Navier-Stokes equations. The prime velocities represent an intermediate velocity field prediction prior to being modified to account for pressure to obtain the actual velocities. The prime velocities (also called a “velocity field”) are solved using previously generated turbulator effects. At operation 816, a pressure correction equation is solved, using at least the prime velocities. At operation 818, utilizing at least a pressure field obtained from the pressure correction equation, the prime velocities are corrected.

At operation 820, a fluid concentration equation representing different wellbore fluids is solved, to arrive at the fluid positions in the annulus at a given moment in time as the simulation proceeds.

At operation 822, a plurality of fluid properties are updated. The plurality of fluid properties includes but is not limited to: density, rheology, diffusion coefficient, etc. The updated fluid properties are based at least in part on new fluid positions indicated by the pressure field.

At operation 824, at least operations 814 through 822 are repeated in a time loop until the completion of the simulation 800. In embodiments, the simulation completes when an entire wellbore cementing operation (and the impact of the turbulator thereon) is simulated (the “full completion time”). In such embodiments, each time loop simulates a smaller, fixed amount of time than the full completion time, and all of the time loops together cover the full competition time. In some such embodiments, the full completion time is divided into a plurality of time loops allows for more efficient use of available computing resources by, e.g., enabling each loop to be run on computing hardware that would not be suitable to simulate the full completion time, or enabling parallel processing.

At operation 826, the fluid positions in the annulus at the conclusion of the time loop in operation 824 (that is, the fluid positions at the end of the full completion time of the 3D CFD turbulator model simulation) are output as a 3D CFD result, and the 3D CFD result includes a simulated annular placement of cement.

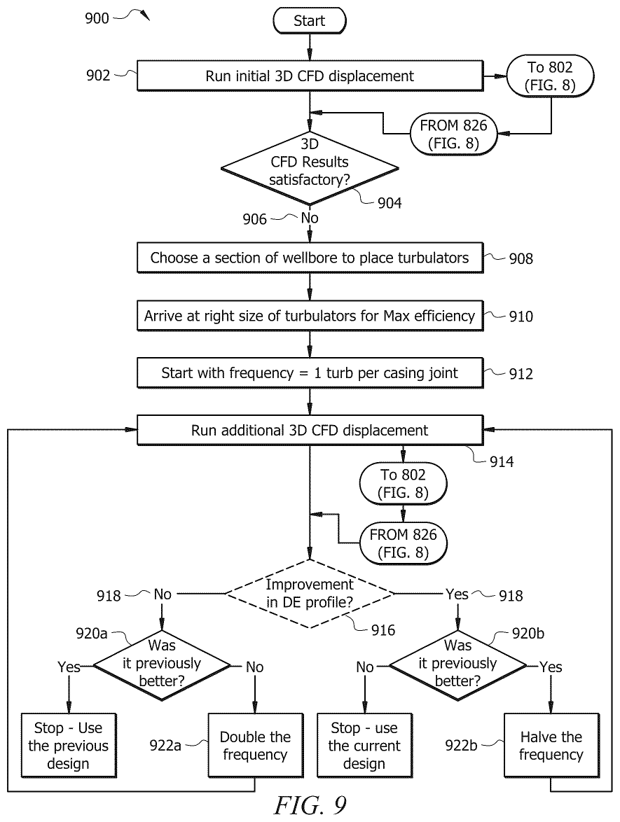

Turning now to FIG. 9, a process flow 900 (also called the “simulation 900” herein) for a CFD-based simulation model for determining turbulator spacing is illustrated according to an embodiment of the disclosure. At operation 902, a user runs an initial 3D CFD simulation of a cementing operation that is in the planning stage. In some embodiments, the initial 3D CFD simulation uses the technique of FIG. 8 and process flow 800, herein. At operation 904, the user observes the resulting simulated annular placement of cement (e.g., the 3D CFD result of operation 826), and, at operation 906, determines that the simulated annular placement of cement exhibits an insufficient DE.

Upon determining the simulated DE is insufficient, at operation 908 a section of the simulated wellbore is chosen. At least one simulated turbulator will be placed within the section of simulated wellbore to adjust the observed DE. At operation 910, a size and a type of turbulator are chosen to maximize efficiency of the turbulator. The choice is based on at least characteristics of the wellbore. Such characteristics include but are not limited to measurements of the wellbore, measurements of the casing, and stand-off values.

At operation 912, prior to an additional 3D simulation being performed, the turbulator spacing is set to one turbulator per joint. In some embodiments, this equates to one turbulator per forty feet of casing. At operation 914, an additional 3D CFD simulation is run. At operation 916, the additional simulation is analyzed by the user to determine a change in a DE profile.

At operation 918, the user determines whether the DE profile was more desirable before the determined change in the DE profile.

Which of operations 920a and 920b is executed as part of the process flow 900 is determined as follows:
Operation 920a: If the DE profile did not improve and was not previously better than the changed DE profile, the frequency of turbulators is doubled at operation 922A and the simulation 900 is repeated, beginning at operation 914. However, if the DE profile did not improve and was previously better than the changed DE profile, then the previous number of turbulators is used and the simulation 900 ends.
Operation 920b: If the DE profile did improve and was not previously better than the changed DE profile, then the current number of turbulators is used and the simulation 900 ends. Otherwise, if the DE profile did improve from the initial simulation run at operation 902, but was previously better, then the frequency of turbulators is halved at operation 922B and the simulation 900 continues from operation 914.

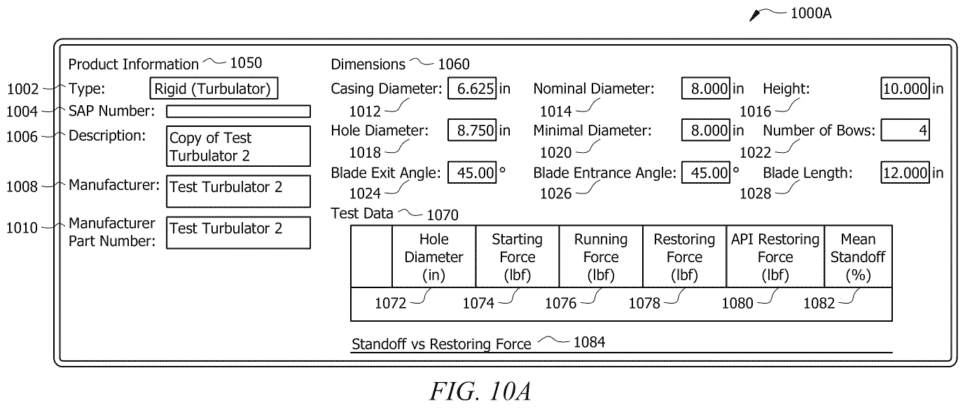

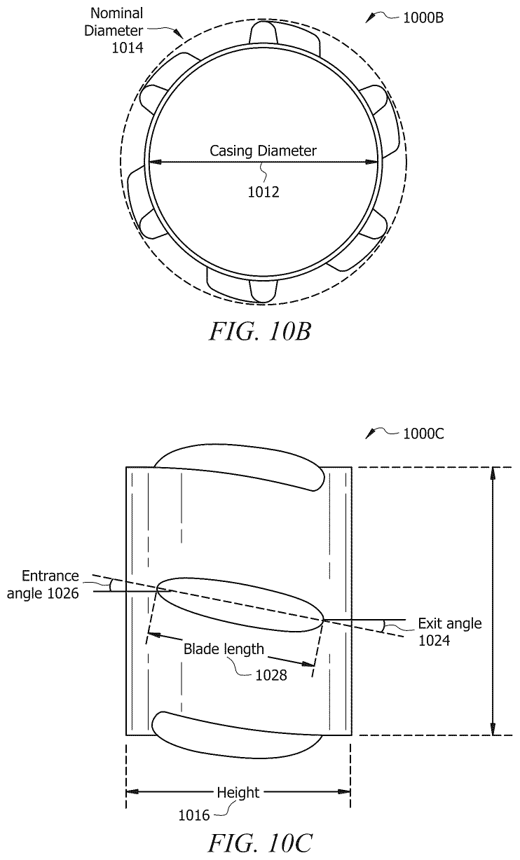

Turning now to FIGS. 10A-10C, a user interface 1000A for inputting turbulator data and turbulator data inputs associated with a simulation of an impact of a turbulator 1000B, 1000C on a wellbore cementing operation is illustrated according to an embodiment of the disclosure. In embodiments herein, the turbulator 1000B and the turbulator 1000C are the same turbulator shown in different views; the turbulator 1000B is illustrated with a cross-sectional view, while the turbulator 1000C is illustrated with a side elevational view. The user interface 1000A includes inputs for product information 1050 and turbulator dimensions 1060. Output includes a record of a current test data 1070.

In some embodiments, the product information 1050 includes but is not limited to: a turbulator type 1002, an SAP number 1004, a description 1006, a manufacturer 1008, and a manufacturer part number 1010. In other embodiments, not all of the foregoing are included in the product information 1050. In some embodiments, turbulator dimensions 1060 include but are not limited to a casing diameter 1012 (measured in feet), a nominal diameter 1014 (measured in inches), a height 1016 (measured in inches), a borehole diameter 1018 (measured in inches), a minimal diameter 1020 (measured in inches), a number of bows 1022, and a blade length 1028 (measured in inches).

In some embodiments, the test data 1070 includes but is not limited to a borehole diameter 1072 (measured in inches, and in some embodiments equal to the borehole diameter 1018), a starting force (measured in pounds of force (lbf)) 1074, a running force (measured in lbf) 1076, a restoring force 1078 (measured in lbf), an API restoring force 1080 (measured in lbf), a mean standoff (represented as a percentage) 1082, and an indicator of standoff versus restoring force 1084. At least some of the test data 1070 listed above is calculated based on at least one of the turbulator dimensions 1060.

The turbulator 1000B, 1000C of FIGS. 10B-10C is a hypothetical turbulator. The turbulator 1000B, 1000C is annotated to indicate where various turbulator dimensions 1060 are found. These include but are not limited to the nominal diameter 1014, the casing diameter 1012, the blade entrance angle 1026, the blade exit angle 1024, the blade length 1028, and the height 1016.

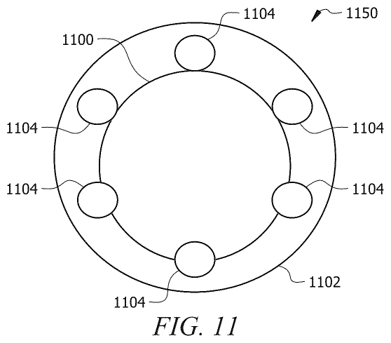

Turning now to FIG. 11, a side elevational view of a casing string 1100 mechanically coupled to a plurality of turbulators 1104 placed within an axial cell within a wellbore 1150 is illustrated according to an embodiment of the disclosure. The wellbore has an annulus 1102. The placement of the plurality of turbulators 1104 within a single axial cell enables overlap effects. The overlap effects synergistically amplify the impact of the plurality of turbulators 1104 on the DE of cement during a cementing operation. These overlap effects thus further reduce or eliminate channeling within the axial cell during the cementing operation.

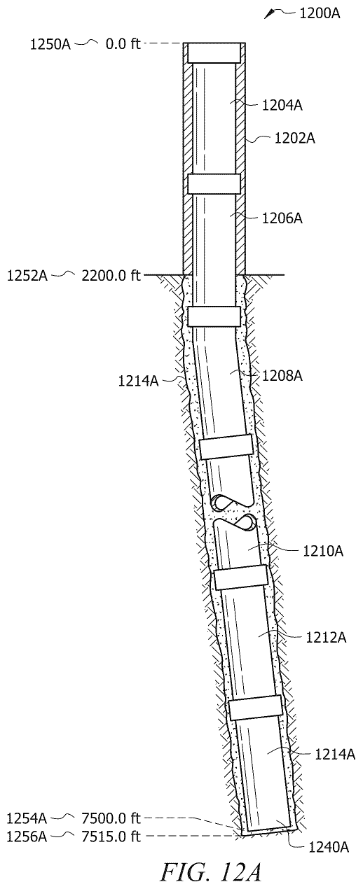

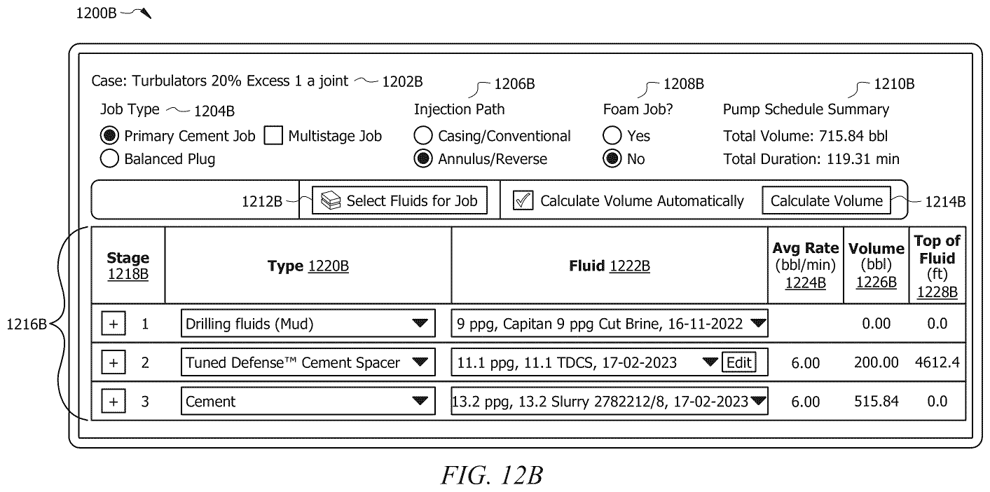

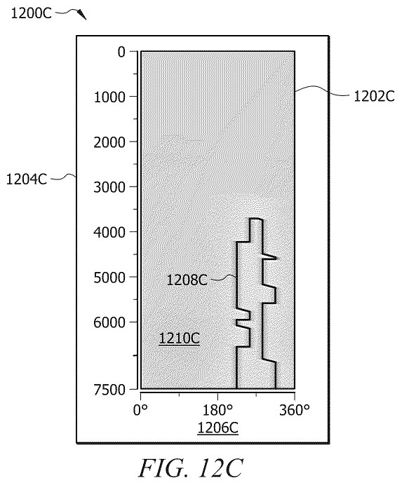

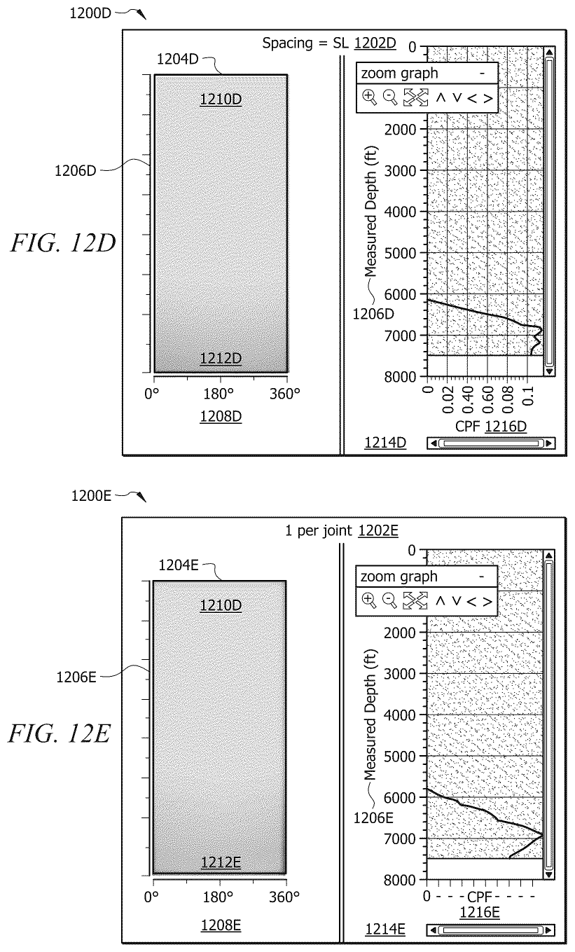

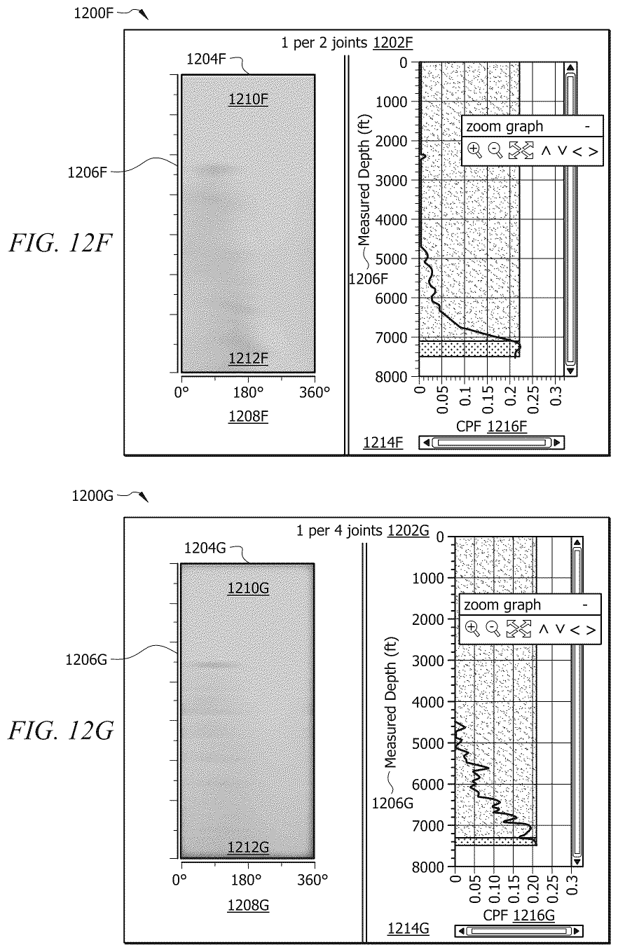

FIGS. 12A-17B below explore three example applications to hypothetical wellbore cementing jobs of the 3D CFD-based model disclosed herein. Collectively, they are the “three Example Applications” or “Example Application 1,” “Example Application 2,” and “Example Application 3.” In the three Example Applications, hypothetical turbulators are applied in the configurations indicated therein, and the corresponding effects are simulated. For ease of interpretation, the structure of the results of the three Example Applications utilize a common style of presentation.

The common style of presentation is described in the table below. The channel potential factor (CPF) plots discussed below are associated with each unrolled view of an annulus showing fluid concentration, as indicated in the table below. The CPF is determined by solving a CPF equation for a cross-section of a wellbore being analyzed. The CPF equation for a given cross-section is:

$${CPF = ( \frac{standard deviation of cell concentration}{Standard deviation o f ideal unmixed system} )}_{cross section}$$

The CPF is evaluated at each cross-section of the wellbore annulus, and then plotted along the depth. A CPF that is equal to zero indicates a completely mixed system of fluids at a given cross section, while a CPF equal to one indicates complete channeling of a particular fluid. As explained further elsewhere herein, such channeling is detrimental to the integrity of a wellbore. The systems and methods of this disclosure thus enable identifying and mitigating such channeling. The standard deviation is calculated for each CFD mesh cell at the cross-section.

In light of the foregoing, in the Example Applications, the x-axis of the provided CPF plots indicates a fluid concentration at a given section of a wellbore. Sections with a CPF value greater than 0.4 and CPF less than 0.2 are indicated visually. This visual coding enables interpreting the regions where the cement distribution is subject to improvement by adjusting the cement job design.

As used in embodiments herein, each predictive bond log (PBL) plot captures the total cement concentration plotted along the depth of the wellbore. In embodiments featuring lead and tail cements as those terms are understood by a person having ordinary skill in the art, the total cement concentration is the summation of the lead and tail cement concentrations.

Example Applications Table:

| | | | | | | Channel |
|---|---|---|---|---|---|---|
| | | | | | Predictive | Potential |
| | | | Simulation | Simulation Results | Bond Log | Factor |
| Example | Wellbore | Pump | Results (No | (Various Turbulator | (PBL) | (CPF) |
| Applications | Geometry | Sched. | Turbulator) | Spacings) | Plots | Plots |
| Example | FIG. | FIG. | FIG. | FIGS. | FIG. | FIG. |
| Application 1 | 12A | 12B | 12C | 12D-12G | 13A | 13B |
| Example | FIG. | FIG. | FIG. | FIGS. | FIG. | FIG. |
| Application 2 | 14B | 14A | 14C | 14D-14G | 15A | 15B |
| Example | FIG. | FIG. | FIG. | FIG. | FIG. | FIG. |
| Application 3 | 16B | 16A | 16C | 16D-16G | 17A | 17B |

Turning now to FIGS. 12A-12G, a user interface 1200B and output of a CFD-based simulation model of turbulator spacing for a wellbore 1200A reverse cementing job is illustrated according to an embodiment of the disclosure. Various measurements in the following description are provided for exemplary purposes only and not intended to limit the scope of this disclosure in any way.

In the simulated wellbore 1200A, the wellbore 1202A is drilled into a surface 1250A, and descends past a first depth 1252A (e.g., 2200.0 feet) and a second depth 1254A (e.g., 7500.0 feet) to a third depth 1256A (e.g., 7515.0 feet). A casing 1240A comprises a first joint 1204A, a second joint 1206A, a third joint 1208A, a fourth joint 1210A, a fifth joint 1212A, and a sixth joint 1214A. The casing 1240A is located within an annulus 1216A.

Embodiments of the user interface 1200B are configured to enable a user to define the characteristics of a hypothetical pumping schedule 1216B to be simulated using the systems and methods of this disclosure and include but are not limited to the following elements.
Turbulator Configuration (or “Case”) 1202B: A turbulator configuration per joint to be simulated.
Job Type 1204B: The type of cementing job to be simulated (e.g., primary cement job, balanced plug, multistage job, etc.). Other embodiments of this disclosure include types of cementing jobs which are not present in FIG. 12B due to space constraints.
Injection Path 1206B: A selector used to simulate either a forward cementing job (including conventional injection inside the casing) or a reverse cementing job (including injection into the annulus).
Foam Job 1208B: A selector to choose whether or not to simulate a foam job as part of the hypothetical pumping schedule 1216B.
Pump Schedule Summary 1210B: Based on selections of the user in the user interface 1200B, the pump schedule summary 1210B displays at least a total volume (e.g., in barrels) and a total duration (e.g., in minutes) of the hypothetical pumping schedule 1216B.

The user indicates what fluids are to be simulated using a fluid selector 1212B, and has access to a volume calculator 1214B. The volume calculator 1214B is optionally configurable to calculate the volume automatically. The hypothetical pumping schedule 1216B includes at least one stage 1218B. For each stage 1218B, the user specifies a fluid type 1220B (e.g., mud, cement spacer, cement, etc.), and a specific fluid 1222B of the fluid type 1220B. For each stage 1218B, the simulation displays an average rate (e.g., in barrels per minute) 1224B, a volume (e.g., in barrels) 1226B, and a top of fluid (e.g., in feet) 1228B.

FIG. 12C illustrates simulation results 1200C where no turbulator is present. Locations in an unrolled annulus 1202C are indicated by a depth 1204C (e.g., in feet) and a corresponding location 1206C in an equivalent rolled up annulus, measured in, for example, degrees. In alternative embodiments, the corresponding location 1206C is measured in radians or some other unit of measure suitable for specifying locations inside a rolled up annulus. A channeling 1208C of the cement 1210C is readily apparent in the simulation results 1200C.

FIG. 12D illustrates simulation results 1200D, wherein a turbulator spacing 1202D is equal to a swirl length determined as explained elsewhere herein. Locations in an unrolled annulus 1204D are indicated by a depth 1206D (e.g., in feet) and a corresponding location 1208D in an equivalent rolled up annulus, measured in, for example, degrees. In alternative embodiments, the corresponding location 1208D is measured in radians or some other unit of measure suitable for specifying locations inside a rolled up annulus. A channeling 1210D of the cement 1212D is also shown in the simulation results 1200D. As shown, the simulation results 1200D, in some examples, make visual appraisal of the degree of channeling difficult. In such examples, a CPF plot 1214D, plotting a CPF 1216D (as described elsewhere herein) against the depth 1206D reveals further information about the actual degree of cement channeling present in the simulation results.

FIGS. 1200E-1200G illustrate simulation results 1200E (having a turbulator spacing 1202E), simulation results 1200F (having a turbulator spacing 1202F), and simulation results 1200G (having a turbulator spacing 1202G). FIGS. 1200E-1200G are provided for exemplary purposes only. Aside from the change in reference number (e.g., CPF 1216D, 1216E, 1216F, 1216G) and differing simulation results corresponding to the difference in turbulator spacing, the numbered elements in FIGS. 1200E-1200G have the same meaning as in the discussion of the simulation results 1200D, and will not be discussed further herein.

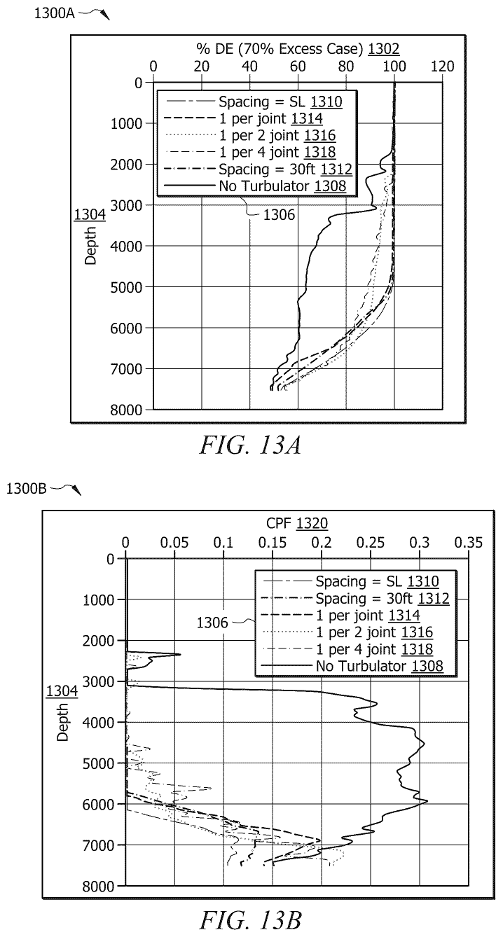

Turning now to FIGS. 13A and 13B, a PBL plot 1300A and a CPF plot 1300B associated with the CFD-based simulation model of turbulator spacing for a wellbore reverse cementing job of FIGS. 12A-12G are illustrated according to an embodiment of the disclosure. The PBL plot 1300A plots a DE 1302 (representing a seventy percent excess case) against a wellbore depth 1304 (measured in feet). In some embodiments, the seventy percent excess is the excess in the wellbore outer diameter that is considered for various calculations and 3D CFD modeling. For example, if a wellbore diameter is ten units (in any measurement scale), then the seventy percent excess is seventeen units, and the seventy percent excess value is used calculations related to the 3D CFD modeling systems and methods disclosed herein. The PBL plot 1300A is part of only one Example Application. Other example applications, including those not shown here, use a different percent excess. Yet other example applications, including those not shown here, use no percent excess.

On to this plot are laid simulation results 1306 (as best-fit line graphs) of FIGS. 12A-12H as described herein. The simulation results 1306 include simulations of no turbulators 1308, turbulators placed at the swirl length 1310, turbulators placed every thirty feet 1312; turbulators placed one per joint 1314, turbulators placed one per two joints 1316, and turbulators placed one per four joints 1318.

The CPF plot 1300B plots CPF 1320 against the depth 1304 (measured in feet). On to this plot are laid simulation results 1306 (as best-fit line graphs) of FIGS. 12A-12H as described herein. The simulation results 1306 include simulations of no turbulators 1308, turbulators placed at the swirl length 1310, turbulators placed every thirty feet 1312; turbulators placed one per joint 1314, turbulators placed one per two joints 1316, and turbulators placed one per four joints 1318.

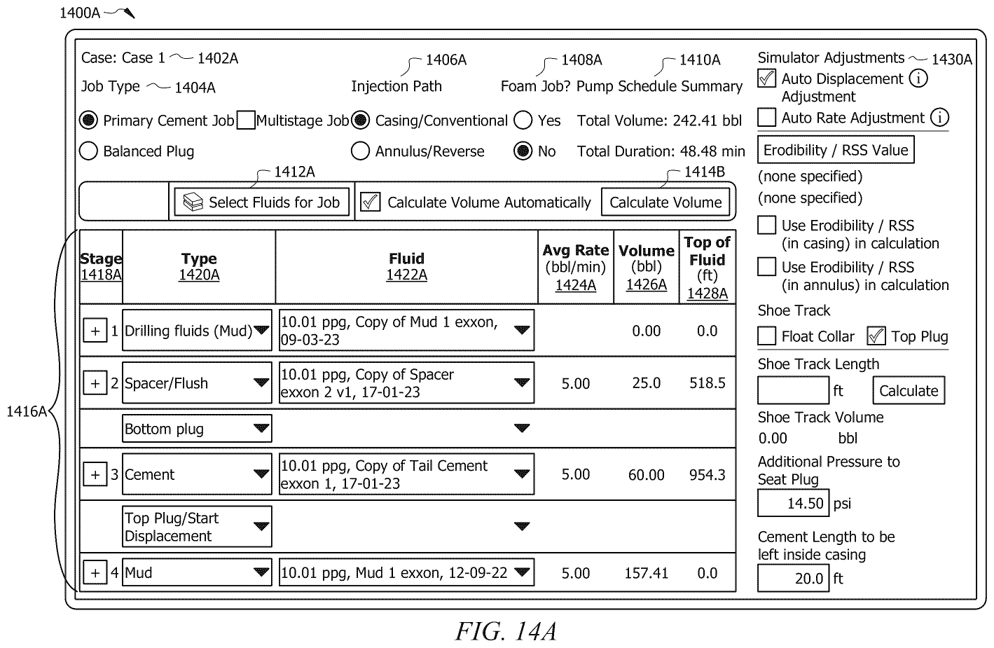

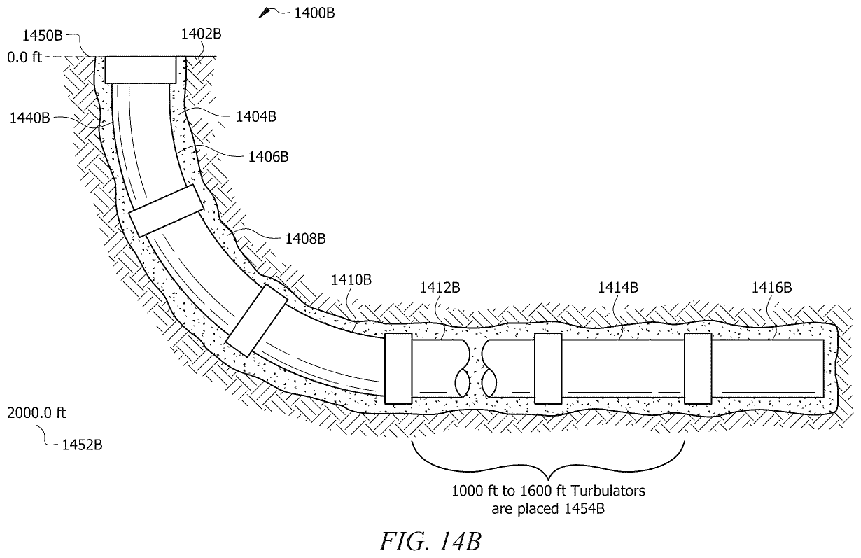

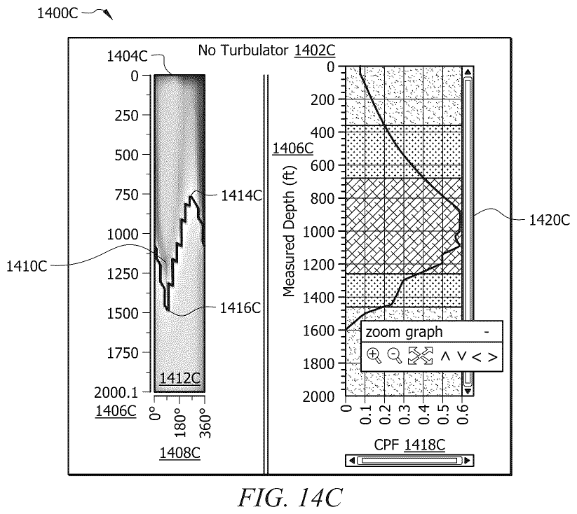

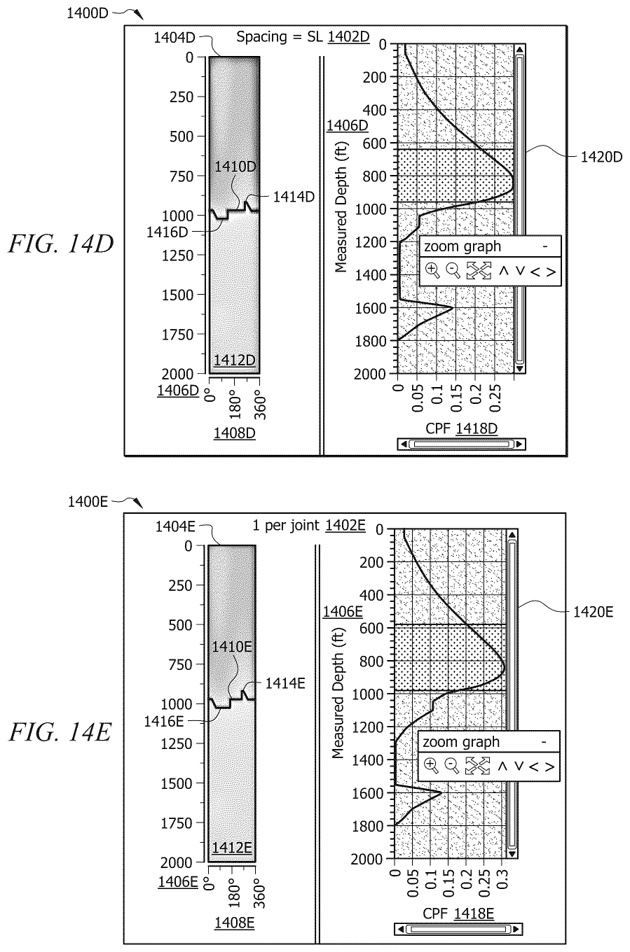

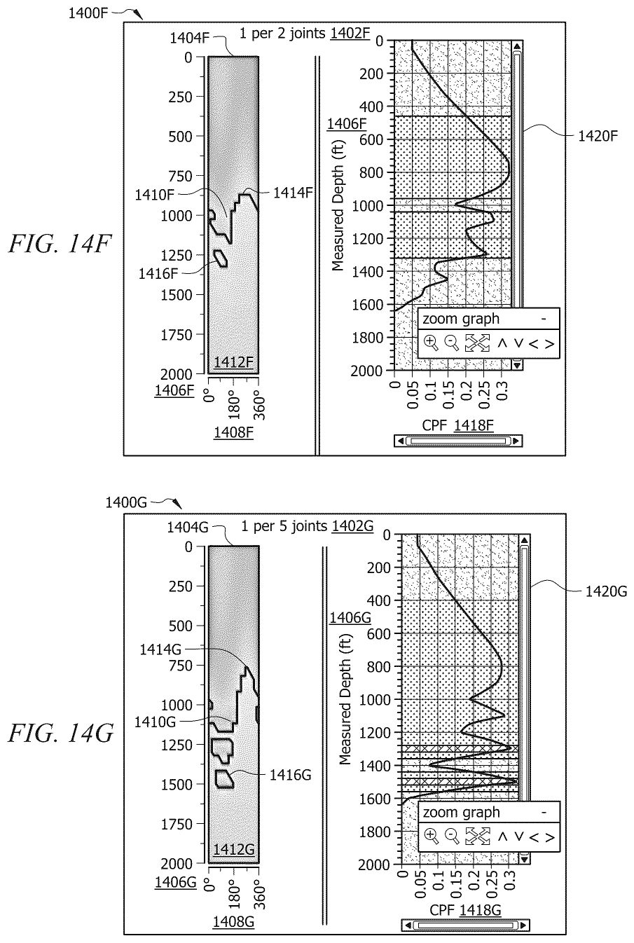

Turning now to FIGS. 14A-14G, a user interface 1400B and output of a CFD-based simulation model of turbulator spacing for a first wellbore 1400A forward cementing job is illustrated according to an embodiment of the disclosure. FIGS. 14A-14G illustrate embodiments wherein the systems and methods disclosed herein are used to model channeling mitigation strategies for an ERD wellbore forward cementing job. Various measurements in the following description are provided for exemplary purposes only and not intended to limit the scope of this disclosure in any way.

FIG. 14A is a user interface 1400A configured to enable a user to define the characteristics of a hypothetical pumping schedule 1416A to be simulated using the systems and methods of this disclosure and include but are not limited to elements 1402A-1428A, which are substantially identical to elements 1202B-1228B above, and will not be discussed further. Additionally, the user interface 1400A also includes simulator adjustments 1430A. The simulator adjustments 1430A provide a number of tunable variables to the user to enable the user to further customize the simulated pumping schedule to more closely match the expected real world conditions for a wellbore servicing operation or cementing operation as discussed elsewhere herein. In various embodiments, the simulator adjustments 1430A include but are not limited to the specific tunable variables shown in FIG. 14A: automatic displacement adjustment; automatic rate adjustment; credibility and RSS values and usage; shoe track information; seat plug pressure information; and cement length inside the casing. Some embodiments contain fewer tunable variables. Other embodiments contain more tunable variables.

FIG. 14B illustrates a side elevational view of the simulated wellbore 1400B. In the simulated wellbore 1400B, the wellbore 1402B is drilled into a surface 1450B, and descends to a first depth 1452B (e.g., 2000.0 feet). A lateral extension 1454B extends laterally from, e.g., 1000.0 feet to 1600.0 feet as shown. In the example of the simulated wellbore 1400B, the simulation of turbulator placement is confined to the lateral extension 1454B. A casing 1440B is situated within an annulus 1404B and is divided into joints 1406B-1416B.

FIG. 14C illustrates 3D CFD model-based simulation results 1400C for the planned cementing job specified using the user interface 1400A when no turbulators 1402C are used. Locations within an unrolled view of the annulus 1404C are plotted as a depth 1406C (e.g., measured in feet) against a corresponding location 1408C in an equivalent unrolled annulus, measured in, for example, degrees. In alternative embodiments, the corresponding location 1408C is measured in radians or some other unit of measure suitable for specifying locations inside a rolled up annulus. A channeling 1410C of the cement 1412C is readily apparent in the simulation results 1400C. In this example, the channeling 1410C occurs from a first depth 1414C of seven-hundred-and-fifty feet to a second depth 1416C of fifteen-hundred feet. A corresponding CPF plot 1418C shows a region 1420C indicating a potential for channeling. By making the potential channeling detectable in the simulation results 1400C, the 3D CFD model-based systems and methods disclosed herein enable mitigating the channeling while the cementing job is still in the planning phase.

FIGS. 1400D-1400G illustrate example simulation results 1400D (having a turbulator spacing 1402D equal to the swirl length as discussed elsewhere herein), simulation results 1400E (having a turbulator spacing 1402E of one per joint), simulation results 1400F (having a turbulator spacing 1402F of one per two joints), and simulation results 1400G (having a turbulator spacing 1402G of one per five joints) of the 3D CFD-based model simulation of the disclosed systems and methods herein. FIGS. 14D-14G illustrate turbulators employed at different spacings. As shown, the cement distribution in the annulus and the CPF both vary according to the changes in turbulator deployment. FIGS. 1400D-1400G are provided for exemplary purposes only. Aside from the change in reference number (e.g., turbulator spacing 1402D, 1402E, 1402F, 1402G) and differing simulation results corresponding to the difference in turbulator spacing, the numbered elements in FIGS. 1400D-1400G have the same meaning as in the discussion of the simulation results 1400C, and will not be discussed further herein.

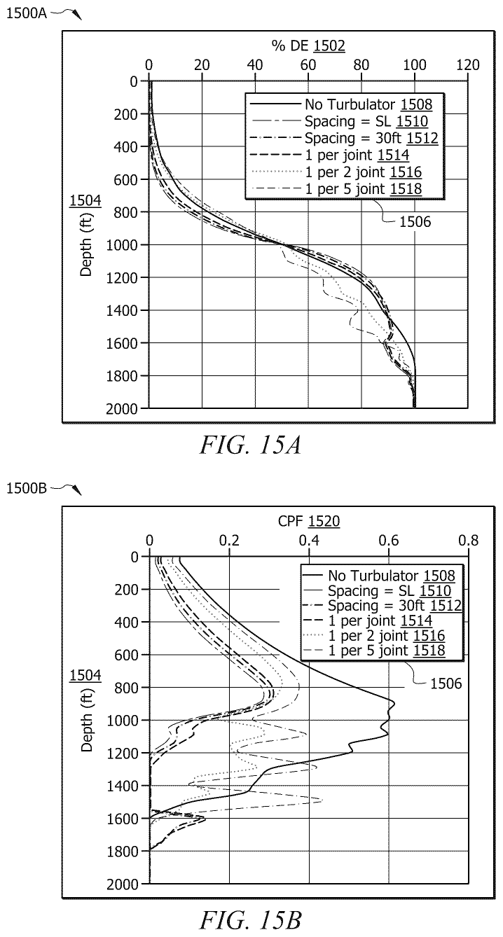

Turning now to FIGS. 15A and 15B, a PBL plot 1500A and a CPF plot 1500B associated with the CFD-based simulation model of turbulator spacing for the first wellbore forward cementing job of FIGS. 14A-14G are illustrated according to an embodiment of the disclosure. The PBL plot 1500A shows the predictive bond log plotted along the depth of the wellbore. As shown, most of the curves indicating different turbulator spacing overlap. This overlapping complicates choosing an optimized turbulator spacing when using the PBL plot 1500A alone. Thus, the CPF plot 1500B is usable in conjunction with the PBL plot 1500A to evaluate the results of turbulator placement simulations. In some embodiments, the impact of the turbulators is magnified on the CPF plot 1500B, aiding the user in choosing an optimized turbulator spacing.

The PBL plot 1500A plots a DE 1502 against a wellbore depth 1504 (measured in feet). On to this plot are laid simulation results 1506 (as best-fit line graphs) of FIGS. 14A-14G as described herein. The simulation results 1506 include simulations of no turbulators 1508, turbulators spaced according to the swirl length 1510, turbulators placed every thirty feet 1512, turbulators placed one per joint 1514, turbulators placed one per two joints 1516, and turbulators placed one per five joints 1518.

The CPF plot 1500B plots CPF 1520 against the depth 1504 (measured in feet). On to this plot are laid the simulation results 1506 (as best-fit line graphs) of FIGS. 14A-14G as described herein. The simulation results 1506 include simulations of no turbulators 1508, turbulators spaced according to the swirl length 1510, turbulators placed every thirty feet 1512, turbulators placed one per joint 1514, turbulators placed one per two joints 1516, and turbulators placed one per five joints 1518.

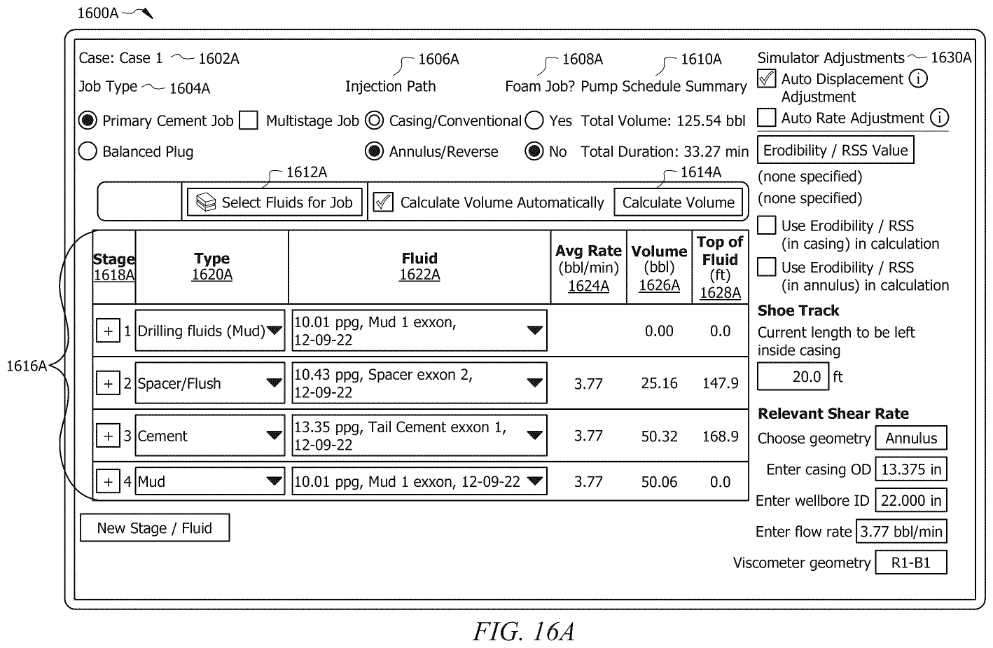

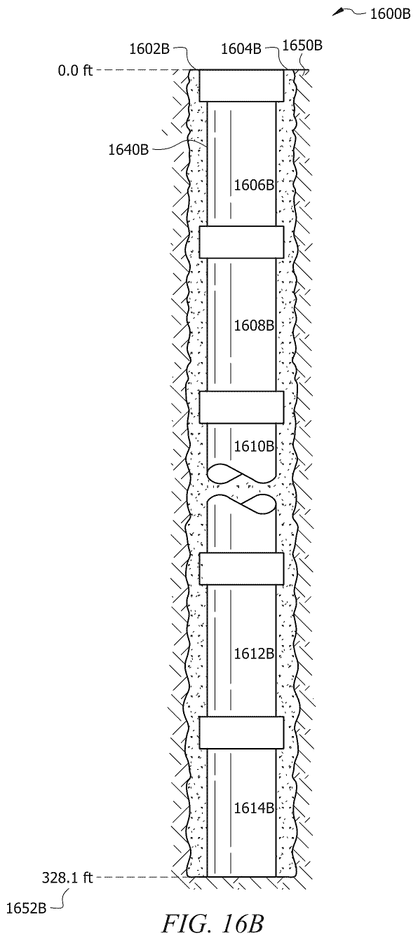

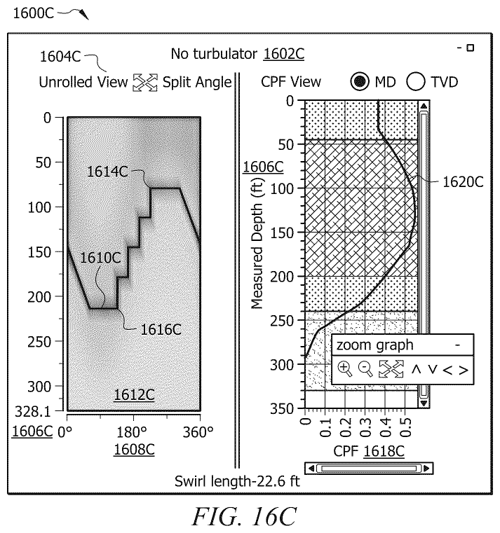

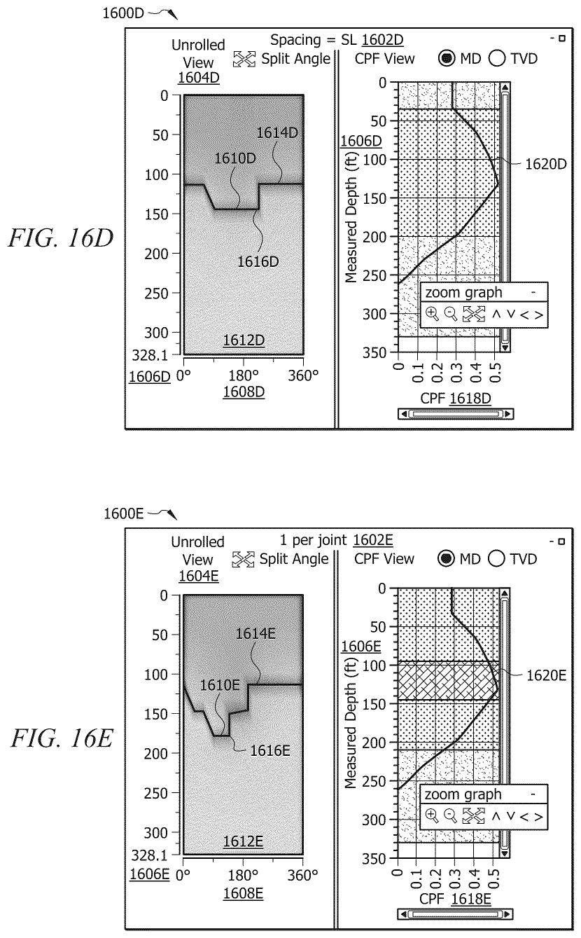

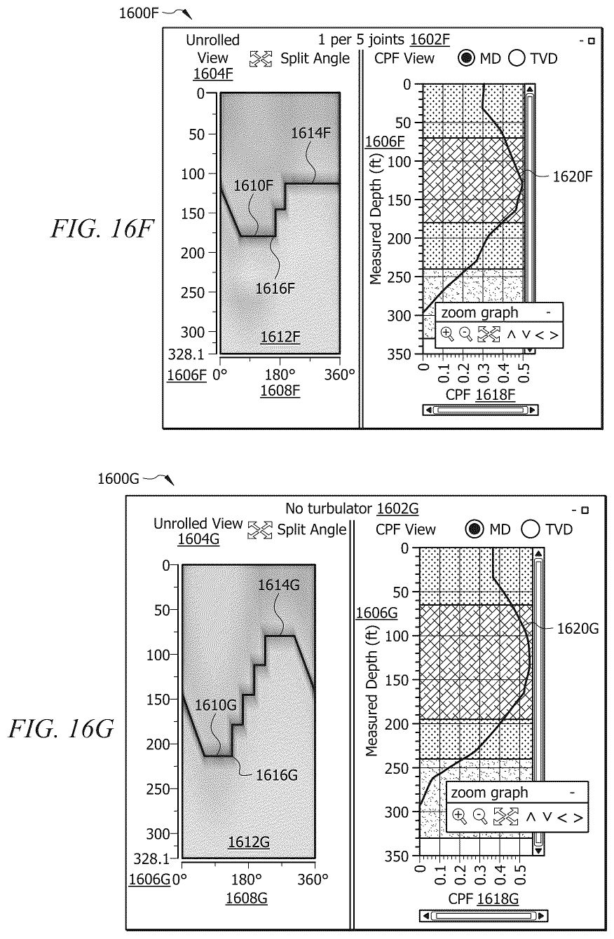

Turning now to FIGS. 16A-16G, a user interface 1600A and output of a CFD-based simulation model of turbulator spacing for a second wellbore 1600B forward cementing job is illustrated according to an embodiment of the disclosure. Various measurements in the following description are provided for exemplary purposes only and not intended to limit the scope of this disclosure in any way.

FIG. 16A is a user interface 1600A configured to enable a user to define the characteristics of a hypothetical pumping schedule 1616A to be simulated using the systems and methods of this disclosure and include but are not limited to elements 1602A-1628A, which are substantially identical to elements 1202B-1228B above, and will not be discussed further. Additionally, the user interface 1600A also includes simulator adjustments 1630A. The simulator adjustments 1630A provide a number of tunable variables to the user to enable the user to further customize the simulated pumping schedule to more closely match the expected real world conditions for a wellbore servicing operation or cementing operation as discussed elsewhere herein. In various embodiments, the simulator adjustments 1630A include but are not limited to the specific tunable variables shown in FIG. 16A: automatic displacement adjustment; automatic rate adjustment; credibility and RSS values and usage; shoe track information; seat plug pressure information; and relevant shear rate. Some embodiments contain fewer tunable variables. Other embodiments contain more tunable variables.

FIG. 16B illustrates a side elevational view of the simulated wellbore 1600B. In the simulated wellbore 1600B, the wellbore 1602B is drilled into a surface 1650B, and descends to a first depth 1452B (e.g., 328.1 feet). A casing 1640B is situated within an annulus 1604B and is divided into joints 1606B-1614B.

FIG. 16C illustrates 3D CFD model-based simulation results 1600C for the planned cementing job specified using the user interface 1600A when no turbulators 1602C are used. Locations within an unrolled view of the annulus 1604C are plotted as a depth 1606C (e.g., measured in feet) against a corresponding location 1608C in an equivalent unrolled annulus, measured in, for example, degrees. In alternative embodiments, the corresponding location 1608C is measured in radians or some other unit of measure suitable for specifying locations inside a rolled up annulus. A channeling 1610C of the cement 1612C is readily apparent in the simulation results 1600C. In this example, the channeling 1610C occurs from a first depth 1614C of seventy-five feet to a second depth 1616C of approximately two-hundred-and-twenty feet. A corresponding CPF plot 1618C shows a region 1620C indicating a potential for channeling. By making the potential channeling detectable in the simulation results 1600C, the 3D CFD model-based systems and methods disclosed herein enable mitigating the channeling while the cementing job is still in the planning phase.

FIGS. 1600D-1600G illustrate example simulation results 1600D (having a turbulator spacing 1602D equal to the swirl length as discussed elsewhere herein), simulation results 1600E (having a turbulator spacing 1602E of one per joint), simulation results 1600F (having a turbulator spacing 1602F of one per two joints), and simulation results 1600G (having a turbulator spacing 1602G of one per five joints) of the 3D CFD-based model simulation of the disclosed systems and methods herein. FIGS. 16D-16G illustrate turbulators employed at different spacings. As shown, the cement distribution in the annulus and the CPF both vary according to the changes in turbulator deployment. FIGS. 1600D-1600G are provided for exemplary purposes only. Aside from the change in reference number (e.g., turbulator spacing 1602D, 1602E, 1602F, 1602G) and differing simulation results corresponding to the difference in turbulator spacing, the numbered elements in FIGS. 1600D-1600G have the same meaning as in the discussion of the simulation results 1600C, and will not be discussed further herein.

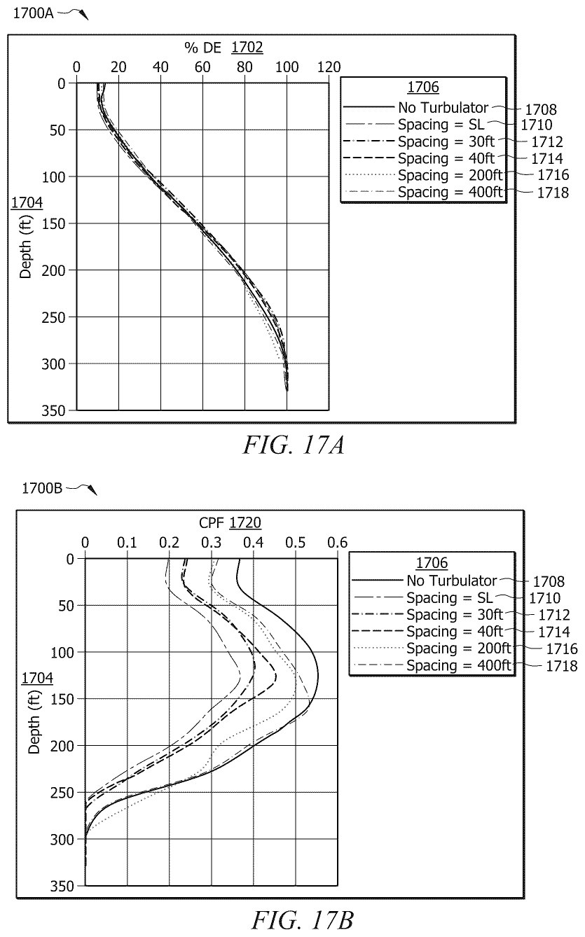

Turning now to FIGS. 17A and 17B, a PBL plot 1700A and a CPF plot 1700B associated with the CFD-based simulation model of turbulator spacing for the second wellbore forward cementing job of FIGS. 16A-16G. The PBL plot 1700A plots a DE 1702 against a wellbore depth 1704 (measured in feet). On to this plot are laid simulation results 1706 (as best-fit line graphs) of FIGS. 16A-16G as described herein. The simulation results 1706 include simulations of no turbulators 1708, turbulators spaced according to the swirl length 1710, turbulators placed every thirty feet 1712, turbulators placed every forty feet 1714, turbulators placed every two-hundred feet 1716, and turbulators placed every four hundred feet 1718.

The CPF plot 1700B plots CPF 1720 against the depth 1704 (measured in feet). On to this plot are laid simulation results 1706 (as best-fit line graphs) of FIGS. 14A-14G as described herein. The simulation results 1706 include simulations of no turbulators 1708, turbulators spaced according to the swirl length 1710, turbulators placed every thirty feet 1712, turbulators placed every forty feet 1714, turbulators placed every two-hundred feet 1716, and turbulators placed every four hundred feet 1718.

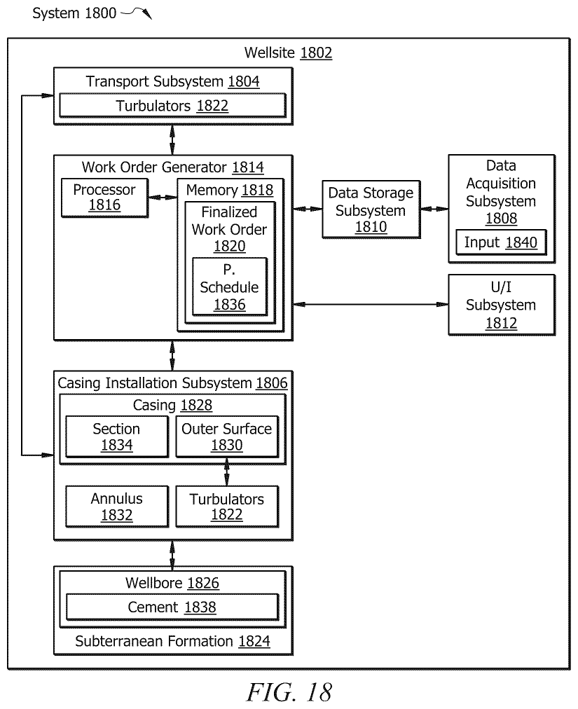

Turning now to FIG. 18, a block diagram of a system 1800 for performing a wellbore cementing operation on a wellbore 1826 according to an embodiment of the disclosure is illustrated. The system 1800 comprises a wellsite 1802 having a transport subsystem 1804 and a casing installation subsystem 1806; and a data acquisition subsystem 1808 communicatively coupled to a data storage subsystem 1810, a user interface subsystem 1812, and a work order generator 1814. The work order generator 1814 has a processor 1816 communicatively coupled to a non-transitory memory 1818. The system 1800 further includes a finalized work order 1820 for a designed cementing operation generated by the work order generator 1814 and stored in the non-transitory memory 1818.

The wellsite 1802 is configured to perform operations comprising: (I) (a) transporting, via the transport system 1804, a number of turbulators 1822 having designated mechanical properties to the wellsite 1802. The wellsite 1802 has the wellbore 1826 penetrating a subterranean formation 1824. The wellsite 1802 is further configured to perform additional operations comprising: (b) installing, via the casing installation subsystem 1806, a casing 1828 in the wellbore 1826, wherein: an outer surface 1830 of the casing 2828 forms an annulus 1832, the number of turbulators 1822 are coupled to the outer surface 1830 of the casing 1828, and the number of turbulators 1822 are disposed and spaced within the annulus 1832 of a section 1834 of the casing 1828 of the wellbore 1826 in accordance with a turbulator spacing of the finalized work order 1820; and (c) pumping, in accordance with a pumping schedule 1836 of the finalized work order 1820, cement 1838 into the annulus 1832, wherein the cement 1838 contacts the number of turbulators 1822 during the pumping, and the number of turbulators 1822 are configured to induce turbulence within the cement 1838 to at least reduce channeling of the cement 1838 within the annulus 1832.

Within the system 1800, the work order generator 1814 is configured to generate the finalized work order 1820 based on preparing a work order associated with the wellbore cementing operation in a planning phase by executing operations comprising: (a) collecting by the data acquisition subsystem 1808 via the user interface subsystem 1812 an input 1840 from a user and storing the input 1840 in the data storage subsystem 1810; (b) based on the input 1840 of the user, running an initial three-dimensional (3D) computational fluid dynamics (CFD)-based simulation of the cementing operation, the initial 3D CFD-based simulation outputting a 3D CFD result comprising a simulated annular placement of a cement within an annulus of a wellbore, the wellbore having a wellbore geometry, and a displacement efficiency (DE); (c) based on the input 1840 of the user, determining that the simulated annular placement of the cement from the initial 3D CFD-based simulation exhibits an insufficient DE within the annulus 1832 of the wellbore; (d) based on the input 1840 of the user, choosing the section 1834 of the casing 1828 of the wellbore 1826, the section 1834 comprising a length of the casing 1828 from a first point to a second point; and (e) simulating mechanically coupling a turbulator 1822 to the section 1834 of the casing 1828 of the wellbore 1826 prior to the installation of the casing 1828 within the wellbore 1826, the turbulator 1822 configured to adjust the DE of the cement 1838 within the annulus 1832 and proximate to the section 1834 of the casing 1828 during the wellbore cementing operation;

The work order generator 1814 is further configured to perform additional operations comprising: (f) based on the input 1840 of the user, adjusting mechanical properties of the turbulator 1822 to maximize the DE of the cement 1838 within the section 1834 during the wellbore cementing operation (the mechanical properties including at least the size of the turbulator 1822 and the specifications of the turbulator 1822); (g) creating the work order for a designed cementing operation that comprises adjusting a turbulator spacing along the casing 1828 of the wellbore 1826 to create an adjusted turbulator spacing (the adjusted turbulator spacing being one turbulator per joint); (h) performing an additional 3D CFD-based simulation of the cementing operation with the adjusted turbulator spacing, the additional 3D CFD-based displacement simulation updating and outputting the simulated annular placement of the cement 1838 within the annulus 1832 of the wellbore 1826 and the DE; (i) based on the additional 3D CFD-based simulation, determining a change in the DE; (j) based on the determined change in the DE, adjusting the work order based on a further simulation loop; and (k) after the further simulation loop ends, finalizing the work order for the designed cementing operation to yield the finalized work order 1820 comprising: the designated mechanical properties of each turbulator 1822, the number of turbulators 1822 associated with the section 1834 of the casing 1828 of the wellbore 1826, the turbulator spacing associated with the section 1834 of the casing 1828 of the wellbore 1826. The pumping schedule 1836 comprises a recipe of the cement 1838, a volume of the cement 1838, a pumping rate, a pumping sequence, and an expected fluid profile. The expected fluid profile comprises expected fluid positions of the different wellbore fluids at an end of the wellbore cementing operation.

In some embodiments of the system 1800, at least one of the initial 3D CFD-based simulation or the additional 3D CFD-based simulation further comprises performing additional operations including: receiving, from the user, the wellbore geometry, the pump schedule 1836, the turbulator spacing, and a turbulator geometry to be tested; storing, within the non-transitory memory 1818, the wellbore geometry, the pump schedule 1836, the turbulator spacing, and the turbulator geometry; estimating, using the turbulator geometry and the turbulator spacing, a swirl number, a swirl length and a corresponding boundary condition (BC) to be applied in a momentum solution, the BC represented as an equivalent casing rotation for the section 1834 of the casing 1828 where the turbulator 1822 is placed; solving prime velocities using previously generated turbulator effects; using the prime velocities, solving a pressure correction equation to obtain a pressure field; using the pressure field, correcting the prime velocities; solving a fluid concentration equation representing different wellbore fluids to determine different wellbore fluid positions in a simulated annulus 1832 at a given moment in time as the simulation proceeds; updating a plurality of fluid properties to create a plurality of updated fluid properties, the plurality of updated fluid properties being based at least in part on changes in the different wellbore fluid positions indicated by the pressure field; and repeating, for the duration of a time loop having a plurality of iterations, the additional operations from solving the prime velocities to updating the plurality of fluid properties.

Each of the iterations of the time loop is configured to generate simulation results for a portion of the wellbore cementing operation. The time loop is configured to simulate an entire duration of the wellbore cementing operation by combining the simulation results for all of the iterations of the time loop into the 3D CFD result. The 3D CFD result is based on the different wellbore fluid positions at a final iteration of the plurality of iterations of the time loop and comprises: the simulated annular placement of the cement 1838 within the annulus 1832 of the wellbore 1826, and the DE. In such embodiments, the system 1800 stores the 3D CFD result. In some embodiments of the system 1800, the pump schedule 1836 is iteratively adjusted by the user to enhance the DE.

In some embodiments of the system 1800, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was not greater than the determined change in the DE, operations performed by the work order generator 1814 further comprise: further adjusting the adjusted turbulator spacing by doubling the number of turbulators 1822 per each section 1834 of the casing 1828 of the wellbore 1826; repeating the operations from performing the additional 3D CFD-based simulation with the adjusted turbulator spacing to, based on the additional 3D CFD-based simulation, determining the change in the DE; and repeating the further simulation loop.

In some other embodiments of the system 1800, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was greater than the determined change in the DE, operations performed by the work order generator 1814 further comprise halting the further simulation loop.

In yet other embodiments of the system 1800, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was not greater than the determined change in the DE, operations performed by the work order generator 1814 further comprise halting the further simulation loop

In still other embodiments of the system 1800, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was greater than the determined change in the DE, operations performed by the work order generator 1814 further comprise: further adjusting the adjusted turbulator spacing by halving a number of turbulators per joint; repeating the operations from performing the additional 3D CFD-based simulation with the adjusted turbulator spacing to, based on the additional 3D CFD-based simulation, determining the change in the DE; and repeating the further simulation loop.

In some embodiments of the system 1800, the turbulator geometry of the turbulator 1822 is configured for a type of the wellbore cementing operation selected from the group consisting of a reverse cementing operation or a forward cementing operation. In other embodiments of the system 1800, the turbulator 1822 is selected from the group consisting of a rigid vane turbulator and a strap-on turbulator.

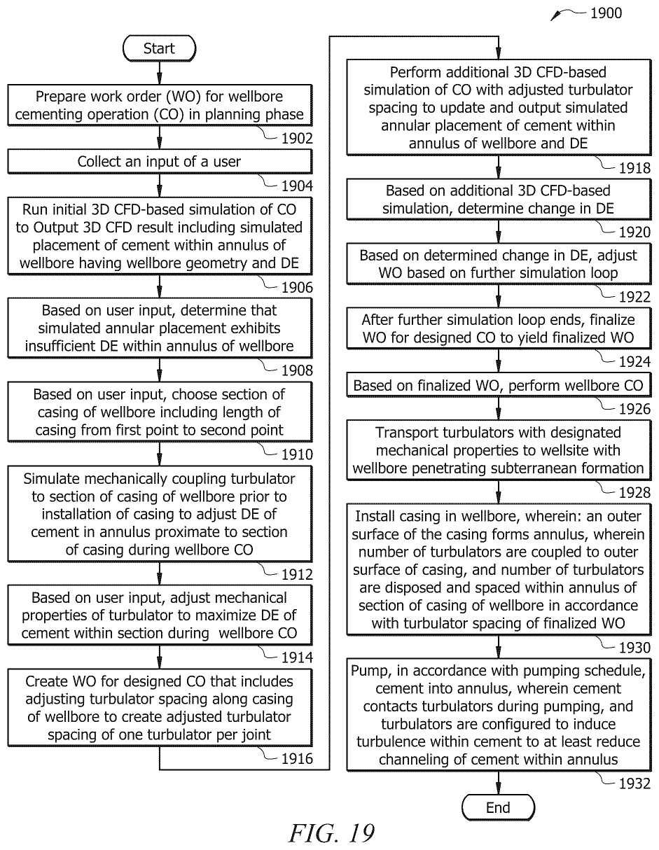

Turning now to FIG. 19, a flow chart of a wellbore servicing method 1900 according to an embodiment of the disclosure is illustrated. At operation 1902, the method 1900 prepares a work order associated with a wellbore cementing operation in a planning phase. The work order results from execution, on a processor communicatively coupled to a non-transitory memory, of operations comprising: at operation 1904, collecting an input of a user, and at operation 1906, running an initial three-dimensional (3D) computational fluid dynamics (CFD)-based simulation of the cementing operation. The initial 3D CFD-based simulation outputting a 3D CFD result comprising a simulated annular placement of a cement within an annulus of a wellbore, the wellbore having a wellbore geometry, and a displacement efficiency (DE). At operation 1908, based on the input of the user, the method 1900 determines that the simulated annular placement of the cement from the initial 3D CFD-based simulation exhibits an insufficient DE within the annulus of the wellbore; at operation 1910, based on the input of the user, choosing a section of a casing of the wellbore, the section comprising a length of the casing from a first point to a second point; at operation 1912, simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation; at operation 1914, based on the input of the user, adjusting mechanical properties of the turbulator to maximize the DE of the cement within the section during the wellbore cementing operation, the mechanical properties including at least the size of the turbulator and the specifications of the turbulator; at operation 1916, creating the work order for a designed cementing operation that comprises adjusting a turbulator spacing along the casing of the wellbore to create an adjusted turbulator spacing, the adjusted turbulator spacing being one turbulator per joint; at operation 1918, performing an additional 3D CFD-based simulation of the cementing operation with the adjusted turbulator spacing, the additional 3D CFD-based displacement simulation updating and outputting the simulated annular placement of the cement within the annulus of the wellbore and the DE; at operation 1920, based on the additional 3D CFD-based simulation, determining a change in the DE; at operation 1922, based on the determined change in the DE, adjusting the work order based on a further simulation loop; and at operation 1924, after the further simulation loop ends, finalizing the work order for the designed cementing operation to yield a finalized work order.

The finalized work order comprises: the designated mechanical properties of each turbulator, a number of turbulators associated with the section of casing of the wellbore, a turbulator spacing associated with the section of the casing of the wellbore, and a pump schedule comprising a recipe of the cement, a volume of the cement, a pumping rate, a pumping sequence, and an expected fluid profile. The expected fluid profile comprises expected fluid positions of the different wellbore fluids at an end of the wellbore cementing operation.

The method 1900 further comprises, at operation 1926, based on the finalized work order, performing the wellbore cementing operation comprising, at operation 1928, transporting the number of turbulators having the designated mechanical properties to a wellsite having the wellbore penetrating a subterranean formation; and at operation 1930, installing the casing in the wellbore. An outer surface of the casing forms the annulus. The number of turbulators are coupled to the outer surface of the casing. The number of turbulators are disposed and spaced within the annulus of the section of the casing of the wellbore in accordance with the turbulator spacing of the finalized work order.

At operation 1932, the method 1900 pumps, in accordance with the pumping schedule, the cement into the annulus. The cement contacts the number of turbulators during the pumping. The number of turbulators are configured to induce turbulence within the cement to at least reduce channeling of the cement within the annulus.

In embodiments of the method 1900, at least one of the initial 3D CFD-based simulation or the additional 3D CFD-based simulation further comprises performing additional operations including: receiving, from the user, the wellbore geometry, the pump schedule, the turbulator spacing, and a turbulator geometry to be tested; storing, within the non-transitory memory, the wellbore geometry, the pump schedule, the turbulator spacing, and the turbulator geometry; estimating, using the turbulator geometry and the turbulator spacing, a swirl number, a swirl length and a corresponding boundary condition (BC) to be applied in a momentum solution, the BC represented as an equivalent casing rotation for the section of a casing where the turbulator is placed; solving prime velocities using previously generated turbulator effects; using the prime velocities, solving a pressure correction equation to obtain a pressure field; using the pressure field, correcting the prime velocities; solving a fluid concentration equation representing different wellbore fluids to determine different wellbore fluid positions in a simulated annulus at a given moment in time as the simulation proceeds; updating a plurality of fluid properties to create a plurality of updated fluid properties, the plurality of updated fluid properties being based at least in part on changes in the different wellbore fluid positions indicated by the pressure field; and repeating, for the duration of a time loop having a plurality of iterations, the additional operations from solving the prime velocities to updating the plurality of fluid properties. Each of the iterations of the time loop is to generate simulation results for a portion of the wellbore cementing operation. The time loop is configured to simulate an entire duration of the wellbore cementing operation by combining the simulation results for all of the iterations of the time loop into the 3D CFD result. The 3D CFD result is based on the different wellbore fluid positions at a final iteration of the plurality of iterations of the time loop and comprises the simulated annular placement of the cement within the annulus of the wellbore. and the DE.

In such embodiments, the method 1900 stores the 3D CFD result. In some such embodiments, the pump schedule is iteratively adjusted by the user to enhance the DE.

In some embodiments of the method 1900, the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was not greater than the determined change in the DE. In such embodiments, the method 1900 further comprises: further adjusting the adjusted turbulator spacing by doubling the number of turbulators per each section of the casing of the wellbore; repeating the operations from performing the additional 3D CFD-based simulation with the adjusted turbulator spacing to, based on the additional 3D CFD-based simulation, determining the change in the DE; and repeating the further simulation loop.

In some other embodiments of the method 1900, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was greater than the determined change in the DE, the method 1900 further comprises halting the further simulation loop.

In yet other embodiments of the method 1900, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was not greater than the determined change in the DE, the method 1900 further comprises halting the further simulation loop.

In still other embodiments of the method 1900, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was greater than the determined change in the DE, the method 1900 further comprises: further adjusting the adjusted turbulator spacing by halving a number of turbulators per joint; repeating the operations from performing the additional 3D CFD-based simulation with the adjusted turbulator spacing to, based on the additional 3D CFD-based simulation, determining the change in the DE; and repeating the further simulation loop.

In some embodiments of the method 1900, the turbulator geometry of the turbulator is configured for a type of the wellbore cementing operation selected from the group consisting of a reverse cementing operation or a forward cementing operation. In some other embodiments of the method 1900, the turbulator is selected from the group consisting of a rigid vane turbulator and a strap-on turbulator.

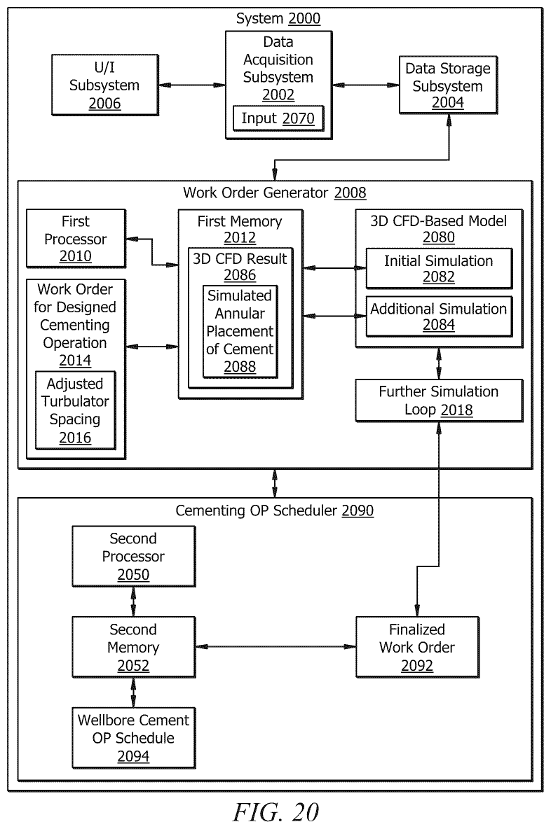

Turning now to FIG. 20, a block diagram of a system 2000 for using a three-dimensional (3D) computational fluid dynamics (CFD)-based model 2080 to prepare a finalized work order 2092 associated with a wellbore cementing operation in a planning phase and to schedule the wellbore cementing operation based on the finalized work order according to an embodiment of the disclosure is illustrated.

The system 2000 comprises a data acquisition subsystem 2002 communicatively coupled to a data storage subsystem 2004, a user interface subsystem 2006, a work order generator 2008, and a wellbore cementing operation scheduler 2090. The work order generator 2008 is further communicatively coupled to the wellbore cementing operation scheduler 2090. The work order generator 2008 comprises a first processor 2010 and a first non-transitory memory 2012.

The work order generator 2008 is configured to perform a first set of operations comprising: (a) collecting by the data acquisition subsystem 2002 via the user interface subsystem 2006 an input 2070 from a user and storing the input 2070 in the data storage subsystem 2004; and (b) based on the input 2070 of the user, running an initial three-dimensional (3D) computational fluid dynamics (CFD)-based simulation 2082 of the cementing operation, the initial 3D CFD-based simulation 2082 outputting a 3D CFD result 2086 comprising a simulated annular placement of a cement 2088 within an annulus of a wellbore. The wellbore has a wellbore geometry. and a displacement efficiency (DE).

The work order generator 2008 is further configured to perform additional operations in the first set of operations, comprising: (c) based on the input 2070 of the user, determining that the simulated annular placement of the cement 2088 from the initial 3D CFD-based simulation 2082 exhibits an insufficient DE within the annulus of the wellbore; (d) based on the input of the user, choosing a section of a casing of the wellbore, the section comprising a length of the casing from a first point to a second point; (e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation; (f) based on the input of the user, adjusting mechanical properties of the turbulator to maximize the DE of the cement within the section during the wellbore cementing operation, the mechanical properties including at least the size of the turbulator and the specifications of the turbulator; and (g) creating the work order for a designed cementing operation 2014 that comprises adjusting a turbulator spacing along the casing of the wellbore to create an adjusted turbulator spacing 2016. The adjusted turbulator spacing is one turbulator per joint.

The work order generator 2008 is further configured to perform additional operations in the first set of operations, comprising: (h) performing an additional 3D CFD-based simulation 2084 of the cementing operation with the adjusted turbulator spacing 2016, wherein the additional 3D CFD-based displacement simulation 2084 updates and outputs the simulated annular placement of the cement 2088 within the annulus of the wellbore and the DE; (i) based on the additional 3D CFD-based simulation 2084, determining a change in the DE; (j) based on the determined change in the DE, adjusting the work order 2014 based on a further simulation loop 2018; and (k) after the further simulation loop 2018 ends, finalizing the work order for the designed cementing operation 2014 to yield the finalized work order 2092. The finalized work order 2092 comprises: the designated mechanical properties of each turbulator, a number of turbulators associated with the section of casing of the wellbore, a turbulator spacing associated with the section of the casing of the wellbore, and a pump schedule comprising a recipe of the cement, a volume of the cement, a pumping rate, a pumping sequence, and an expected fluid profile, the expected fluid profile comprising expected fluid positions of the different wellbore fluids at an end of the wellbore cementing operation.

The system 2000 further comprises the cementing operation scheduler 2090. The cementing operation scheduler 2090 comprises a second processor 2050 and a second non-transitory memory 2052 and is configured to perform a second set of operations comprising: receiving the finalized work order 2092 from the work order generator 2008; and generating a cementing operation schedule 2094 based on the finalized work order 2092. The cementing operation schedule 2094 is configured to at least reduce channeling of the cement within the annulus during the wellbore cementing operation.

In some embodiments of the system 2000, at least one of the initial 3D CFD-based simulation 2082 or the additional 3D CFD-based simulation 2084 further comprises performing additional operations including: receiving, from the user, the wellbore geometry, the pump schedule, the turbulator spacing, and a turbulator geometry to be tested, and storing, within the first non-transitory memory 2012, the wellbore geometry, the pump schedule, the turbulator spacing, and the turbulator geometry. The additional operations further include: estimating, using the turbulator geometry and the turbulator spacing, a swirl number, a swirl length and a corresponding boundary condition (BC) to be applied in a momentum solution, wherein the BC is represented as an equivalent casing rotation for the section of a casing where the turbulator is placed; solving prime velocities using previously generated turbulator effects; using the prime velocities, solving a pressure correction equation to obtain a pressure field; using the pressure field, correcting the prime velocities; solving a fluid concentration equation representing different wellbore fluids to determine different wellbore fluid positions in a simulated annulus at a given moment in time as the simulation proceeds; updating a plurality of fluid properties to create a plurality of updated fluid properties, the plurality of updated fluid properties being based at least in part on changes in the different wellbore fluid positions indicated by the pressure field; and repeating, for the duration of a time loop having a plurality of iterations, the additional operations from solving the prime velocities to updating the plurality of fluid properties. Each of the iterations of the time loop is configured to generate simulation results for a portion of the wellbore cementing operation. The time loop is configured to simulate an entire duration of the wellbore cementing operation by combining the simulation results for all of the iterations of the time loop into the 3D CFD result 2086. The 3D CFD result 2086 is based on the different wellbore fluid positions at a final iteration of the plurality of iterations of the time loop and comprises the simulated annular placement of the cement 2088 within the annulus of the wellbore and the DE. The additional operations further include storing the 3D CFD result 2086.

In some embodiments, a wellbore at a wellsite is treated with a pumping operation. Discussion of a non-limiting example of such an embodiment follows. This discussion does not preclude the utilization of alternative treatments of a wellbore at a wellsite with a pumping operation.

The service personnel transport the wellbore treatment, a pumping procedure, and the pumping equipment, e.g., pump unit 52 of FIG. 1, to the wellsite. The wellbore treatment is designed by the design process utilizing the CFD model. The wellbore treatment comprises a volume of dry ingredients, a volume of chemicals, and various additives that are combined with a liquid, e.g., water, to produce the desired wellbore treatment fluid. In some embodiments, the service personnel fluidically couple the pumping equipment to the wellbore. The wellbore treatment is mixed from the volume of dry ingredients, various chemicals, and water and pumped into the wellbore per the pumping procedure.

In some embodiments, the service personnel identify a deviation or a change to the set of model inputs used to generate the wellbore treatment and pump schedule. For example, in some such embodiments, the wellbore geometry has changed, e.g., the measured depth has been reduced or extended. In another scenario, properties of the liquid, e.g., water, has changed. For example, the water has a higher salt content than the design used in the simulations. The service personnel communicate the deviation to the set of inputs to a remote computer, e.g., a service personnel at a service center, for simulation with the disclosed turbulator impact model. In some embodiments, the service personnel use a wireless communication method, e.g., a mobile communication service.

In some embodiments, the service center personnel utilize the previously described design process with the turbulator impact model on a remote computer to simulate the fluid flow within the wellbore with the revised set of inputs. In some such embodiments, the service center personnel communicate (e.g., with a wireless communication method) a modified wellbore treatment or modified pump schedule to the service personnel at the wellsite.

In some embodiments, the service personnel at the wellsite utilize the previously described design process with the turbulator impact model on a computer system at the wellsite, for example, with the unit controller 60 on the pump unit 52. The design process and turbulator impact model execute on the processor of the unit controller 60. The service personnel input the modified set of inputs into the CFD model executing on the unit controller 60 to determine if any changes are needed to the wellbore treatment or the pump schedule. The design process outputs a modified wellbore treatment and a modified pump schedule. The service personnel communicate the changes to the set of model inputs, the wellbore treatments, and the pump schedule to the remote computer of the service center.

In some embodiments, service personnel at the wellsite couple the pumping equipment to a wellbore via a wellhead, wherein the pumping equipment is fluidically connected to the wellbore. In some such embodiments, the pumping equipment comprises a unit controller, a mixing equipment, and a pumping mechanism. Some exemplary wellbore servicing operations (e.g., cementing operations) can comprise the mixing and the pumping of the well bore treatment per the pump schedule.

In some embodiments, the unit controller begins the cementing operation by controlling the mixing equipment and pumping equipment per the pump schedule. The unit controller retrieves one or more datasets of periodic pumping data indicative of the pumping operation. The unit controller mixes a wellbore treatment, e.g., a cement slurry, comprising a wellbore treatment blend per the pump schedule. The wellbore treatment blend is designed by the design process and the pumping operation simulated with the turbulator impact model.

In some embodiments, the modified wellbore treatment is pumped into the wellbore per the modified pump schedule.

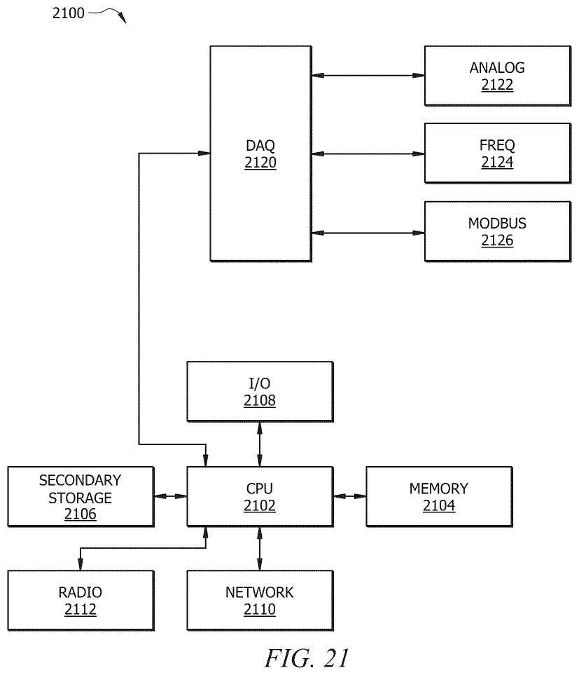

In embodiments herein, the computer system at the wellsite site is a computer system suitable for communication and control of the well treatment operation including pumping equipment via a unit controller. In some embodiments, the unit controller 60 of the pumping equipment, e.g., pump unit 52, of FIG. 1 may be an exemplary computer system 2100 described in FIG. 21. In some embodiments, the computer system located at a remote location is a computer system suitable for communication and analysis of the design of the pump schedule and the pumping operation. For example, in FIGS. 7, 8, and 9, and 18, the process flow 700, the process flow 800, the process flow 900, and the method 1900 can be performed on computer system with the turbulator impact model executing on the same computer system, a networked computer system, or combinations thereof. In some embodiments, the turbulator impact model executes on the same unit controller 60, a networked computer system, a remote computer system, or combinations thereof. In some embodiments, the computer system utilized at the remote location is an exemplary computer system 2100 described in FIG. 21.

Turning now to FIG. 21, a computer system 2100 according to an embodiment of the disclosure is described. The computer system 2100 is suitable for implementing one or more embodiments of the unit controller, for example, unit controller 60 of the pump unit 52, including without limitation any aspect of the computing system associated with the pumping equipment and pumping operation located at a remote wellsite. In some embodiments, the computer system 2100 is at least one of (or at least a component of) the system 1800, the system 2100, or any computer system or combination of computer systems configured to execute the method 1900 described herein. In particular, in some embodiments, the terms unit controller or computer system 2100 are interchangeable. In some embodiments, the computer system 2100 is communicatively connected to embodiments of at least one of the pump 52 or any other component of the cementing operating environment 10 as disclosed herein.

Some embodiments of the computer system 2100 are suitable for implementing one or more embodiments of a remote computer system, for example, a cloud computing system, a virtual network function (VNF) on a network slice of a cloud computing platform, and a plurality of user devices.

The computer system 2100 includes one or more processors 2102 (each also referred to as a “central processor unit,” “central processing unit,” or CPU) that is in communication with a memory 2104, a secondary storage 2106, input/output devices 2108, and network devices 2110. Some embodiments of the computer system 2100 continuously monitor the state of the input devices and change the state of the output devices based on a plurality of programmed instructions. In some embodiments, the programmed instructions comprise one or more applications retrieved from the memory 2104 for executing by the processor 2102 in the non-transitory memory 2104 within the memory 2104. In some embodiments, the input/output devices 2108 comprise a Human Machine Interface with a display screen and the ability to receive conventional inputs from a user such as push button, touch screen, keyboard, mouse, or any other such device or element that a user utilizes to input a command to the computer system 2100. In some embodiments, the secondary storage 2106 comprises at least one of a solid-state memory, a hard drive, or any other type of memory suitable for data storage. In some such embodiments, the secondary storage 2106 additionally optionally comprises at least one of removable memory storage devices such as solid-state memory or removable memory media such as magnetic media and optical media (including without limitation compact discs (CDs), digital versatile discs (DVDs), blu-ray (BD) discs, magneto-optical (MO) discs, etc.).

The computer system 2100 is configured to communicate with various networks utilizing the network devices 2110. In some embodiments, the various networks comprise wired networks utilizing at least one of, e.g., twisted-pair ethernet, direct attach cable (DAC cable), or fiber optic communications equipment, or any other type of wired networking equipment with substantially similar performance characteristics. In other embodiments, the various networks comprise at short range wireless networks such as Wi-Fi (i.e., the IEEE 802.11 family of standards), Bluetooth, or other low power wireless signals such as ZigBee, Z-Wave, 6LoWPan, Thread, and Wi-Fi HaLow, or any other type of wireless networking equipment with substantially similar performance characteristics. In yet other embodiments, the various networks comprise a combination of wired networks and wireless networks as described above. Some embodiments of the computer system 2100 include a long-range radio transceiver 2102 for communicating with mobile network providers.

In some embodiments, the computer system 2100 comprises a data acquisition (DAQ) card 2120 for communication with one or more sensors. In some such embodiments, the DAQ card 2120 is a standalone system with a microprocessor, memory, and one or more applications executing in memory. In some embodiments, the DAQ card 2120, as illustrated, is at least one of a card or a device within the computer system 2100. In some embodiments, the DAQ card 2120 is combined with the input/output device 2108. In some embodiments, the DAQ card 2120 receives one or more analog inputs 2122, one or more frequency inputs 2124, and one or more Modbus inputs 2126. For example, the analog input 2122 may include a volume sensor, e.g., a tank level sensor. In some examples, the frequency input 2124 includes a flow meter, i.e., a fluid system flowrate sensor. In some examples, the modbus input 2126 includes a pressure transducer. In some embodiments, the DAQ card 2120 converts the signals received via the analog input 2122, the frequency input 2124, and the modbus input 2126 into the corresponding sensor data. For example, some embodiments of the DAQ card 2120 converts a frequency input 2124 from the flowrate sensor into flow rate data measured in gallons per minute (GPM).

The systems and methods disclosed herein may be advantageously employed in the context of wellbore servicing operations, particularly, in relation to simulating the effect of turbulators on the displacement of wellbore fluids while cementing as described herein.

In some embodiments, systems and methods disclosed herein, including the methods 1800 or any process executing on the computer system 2100 enable transporting a pump unit to a wellsite having a wellbore penetrating a subterranean formation, wherein the pump unit comprises a unit controller configured to control pumping equipment to pump a treatment fluid into the wellbore, wherein the unit controller comprises a processor and a non-transitory memory; executing a design process on the unit controller, wherein the design process is configured to simulate a three-dimensional (3D) turbulator simulation model by performing operations including: receiving, from a user, a wellbore geometry, a pump schedule, a turbulator spacing, and a turbulator geometry to be tested; storing, within the non-transitory memory, the wellbore geometry, the pump schedule, the turbulator spacing, and the turbulator geometry; estimating, using the turbulator geometry and the turbulator spacing, a swirl number, a swirl length and a corresponding boundary condition (BC) to be applied in a momentum solution, the BC represented as an equivalent casing rotation for a section of a casing where the turbulator is placed; solving prime velocities using previously generated turbulator effects; using the prime velocities, solving a pressure correction equation to obtain a pressure field; using the pressure field, correct the prime velocities; solving a fluid concentration equation representing different wellbore fluids to determine the different wellbore fluid positions in a simulated annulus at a given moment in time as the simulation proceeds; updating a plurality of fluid properties to create a plurality of updated fluid properties, the plurality of updated fluid properties being based at least in part on new fluid positions indicated by the pressure field; repeating solving the prime velocities and the subsequent operations until the simulation is terminated; and generating, by the design process, a purchase order for a plurality of turbulators having the stored turbulator geometry based on the design process.

In some embodiments, systems and methods disclosed herein, including the method 1900 or any process executing on the computer system 2100 enable a wellbore servicing method comprising: (I) preparing a work order associated with a wellbore cementing operation in a planning phase, the work order resulting from execution, on a processor communicatively coupled to a non-transitory memory, of operations comprising: (a) collecting an input of a user; (b) running an initial three-dimensional (3D) computational fluid dynamics (CFD)-based simulation of the cementing operation, the initial 3D CFD-based simulation outputting a 3D CFD result comprising a simulated annular placement of a cement within an annulus of a wellbore, the wellbore having a wellbore geometry, and a displacement efficiency (DE); (c) based on the input of the user, determining that the simulated annular placement of the cement from the initial 3D CFD-based simulation exhibits an insufficient DE within the annulus of the wellbore; (d) based on the input of the user, choosing a section of a casing of the wellbore, the section comprising a length of the casing from a first point to a second point; (e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation; (f) based on the input of the user, adjusting mechanical properties of the turbulator to maximize the DE of the cement within the section during the wellbore cementing operation, the mechanical properties including at least the size of the turbulator and the specifications of the turbulator; (g) creating the work order for a designed cementing operation that comprises adjusting a turbulator spacing along the casing of the wellbore to create an adjusted turbulator spacing, the adjusted turbulator spacing being one turbulator per joint; (h) performing an additional 3D CFD-based simulation of the cementing operation with the adjusted turbulator spacing, the additional 3D CFD-based displacement simulation updating and outputting the simulated annular placement of the cement within the annulus of the wellbore and the DE; (i) based on the additional 3D CFD-based simulation, determining a change in the DE; (j) based on the determined change in the DE, adjusting the work order based on a further simulation loop; and (k) after the further simulation loop ends, finalizing the work order for the designed cementing operation to yield a finalized work order comprising: the designated mechanical properties of each turbulator, a number of turbulators associated with the section of casing of the wellbore, a turbulator spacing associated with the section of the casing of the wellbore, and a pump schedule comprising a recipe of the cement, a volume of the cement, a pumping rate, a pumping sequence, and an expected fluid profile, the expected fluid profile comprising expected fluid positions of the different wellbore fluids at an end of the wellbore cementing operation; (II) based on the finalized work order, performing the wellbore cementing operation comprising: (a) transporting the number of turbulators having the designated mechanical properties to a wellsite having the wellbore penetrating a subterranean formation; (b) installing the casing in the wellbore, wherein: an outer surface of the casing forms the annulus, the number of turbulators are coupled to the outer surface of the casing, and the number of turbulators are disposed and spaced within the annulus of the section of the casing of the wellbore in accordance with the turbulator spacing of the finalized work order; and (c) pumping, in accordance with the pumping schedule, the cement into the annulus, wherein the cement contacts the number of turbulators during the pumping, and the number of turbulators are configured to induce turbulence within the cement to at least reduce channeling of the cement within the annulus.

### Additional Disclosure

The following is provided as additional disclosure for combinations of features and aspects of the present invention.

The following are non-limiting, specific embodiments in accordance with the present disclosure:

A first embodiment is a system for performing a wellbore cementing operation on a wellbore, comprising: a wellsite having a transport subsystem and a casing installation subsystem; a data acquisition subsystem communicatively coupled to a data storage subsystem, a user interface subsystem, and a work order generator, the work order generator having a processor communicatively coupled to a non-transitory memory; a finalized work order for a designed cementing operation generated by the work order generator and stored in the non-transitory memory; (I) the wellsite configured to perform operations comprising: (a) transporting, via the transport system, a number of turbulators having designated mechanical properties to the wellsite having the wellbore penetrating a subterranean formation; (b) installing, via the casing installation subsystem, a casing in the wellbore, wherein: an outer surface of the casing forms an annulus, the number of turbulators are coupled to the outer surface of the casing, and the number of turbulators are disposed and spaced within the annulus of a section of the casing of the wellbore in accordance with a turbulator spacing of the finalized work order; and (c) pumping, in accordance with a pumping schedule of the finalized work order, cement into the annulus, wherein the cement contacts the number of turbulators during the pumping, and the number of turbulators are configured to induce turbulence within the cement to at least reduce channeling of the cement within the annulus; (II) the work order generator configured to generate the finalized work order based on preparing a work order associated with the wellbore cementing operation in a planning phase by executing operations comprising: (a) collecting by the data acquisition subsystem via the user interface subsystem an input from a user and storing the input in the data storage subsystem; (b) based on the input of the user, running an initial three-dimensional (3D) computational fluid dynamics (CFD)-based simulation of the cementing operation, the initial 3D CFD-based simulation outputting a 3D CFD result comprising a simulated annular placement of a cement within an annulus of a wellbore, the wellbore having a wellbore geometry, and a displacement efficiency (DE); (c) based on the input of the user, determining that the simulated annular placement of the cement from the initial 3D CFD-based simulation exhibits an insufficient DE within the annulus of the wellbore; (d) based on the input of the user, choosing the section of the casing of the wellbore, the section comprising a length of the casing from a first point to a second point; (e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation; (f) based on the input of the user, adjusting mechanical properties of the turbulator to maximize the DE of the cement within the section during the wellbore cementing operation, the mechanical properties including at least the size of the turbulator and the specifications of the turbulator; (g) creating the work order for a designed cementing operation that comprises adjusting a turbulator spacing along the casing of the wellbore to create an adjusted turbulator spacing, the adjusted turbulator spacing being one turbulator per joint; (h) performing an additional 3D CFD-based simulation of the cementing operation with the adjusted turbulator spacing, the additional 3D CFD-based displacement simulation updating and outputting the simulated annular placement of the cement within the annulus of the wellbore and the DE; (i) based on the additional 3D CFD-based simulation, determining a change in the DE; (j) based on the determined change in the DE, adjusting the work order based on a further simulation loop; and (k) after the further simulation loop ends, finalizing the work order for the designed cementing operation to yield the finalized work order comprising: the designated mechanical properties of each turbulator, the number of turbulators associated with the section of the casing of the wellbore, the turbulator spacing associated with the section of the casing of the wellbore, and the pumping schedule comprising a recipe/composition of the cement, a volume of the cement, a pumping rate, a pumping sequence, and an expected fluid profile, the expected fluid profile comprising expected fluid positions of the different wellbore fluids at an end of the wellbore cementing operation.

A second embodiment is the system of the first embodiment, wherein at least one of the initial 3D CFD-based simulation or the additional 3D CFD-based simulation further comprises performing additional operations including: receiving, from the user, the wellbore geometry, the pump schedule, the turbulator spacing, and a turbulator geometry to be tested; storing, within the non-transitory memory, the wellbore geometry, the pump schedule, the turbulator spacing, and the turbulator geometry; estimating, using the turbulator geometry and the turbulator spacing, a swirl number, a swirl length and a corresponding boundary condition (BC) to be applied in a momentum solution, the BC represented as an equivalent casing rotation for the section of the casing where the turbulator is placed; solving prime velocities using previously generated turbulator effects; using the prime velocities, solving a pressure correction equation to obtain a pressure field; using the pressure field, correcting the prime velocities; solving a fluid concentration equation representing different wellbore fluids to determine different wellbore fluid positions in a simulated annulus at a given moment in time as the simulation proceeds; updating a plurality of fluid properties to create a plurality of updated fluid properties, the plurality of updated fluid properties being based at least in part on changes in the different wellbore fluid positions indicated by the pressure field; repeating, for the duration of a time loop having a plurality of iterations, the additional operations from solving the prime velocities to updating the plurality of fluid properties, each of the iterations of the time loop being configured to generate simulation results for a portion of the wellbore cementing operation, and the time loop being configured to simulate an entire duration of the wellbore cementing operation by combining the simulation results for all of the iterations of the time loop into the 3D CFD result, the 3D CFD result being based on the different wellbore fluid positions at a final iteration of the plurality of iterations of the time loop and comprising: the simulated annular placement of the cement within the annulus of the wellbore, and the DE; and storing the 3D CFD result.

A third embodiment is the system of the second embodiment, wherein the pump schedule is iteratively adjusted by the user to enhance the DE.

A fourth embodiment is the system of the first embodiment, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was not greater than the determined change in the DE, operations performed by the work order generator further comprising: further adjusting the adjusted turbulator spacing by doubling the number of turbulators per each section of the casing of the wellbore; repeating the operations from performing the additional 3D CFD-based simulation with the adjusted turbulator spacing to, based on the additional 3D CFD-based simulation, determining the change in the DE; and repeating the further simulation loop.

A fifth embodiment is the system of the first embodiment, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was greater than the determined change in the DE, operations performed by the work order generator further comprising halting the further simulation loop.

A sixth embodiment, which is the system of the first embodiment, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was not greater than the determined change in the DE, operations performed by the work order generator further comprising halting the further simulation loop.

A seventh embodiment, which is the system of the first embodiment, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was greater than the determined change in the DE, operations performed by the work order generator further comprising: further adjusting the adjusted turbulator spacing by halving a number of turbulators per joint; repeating the operations from performing the additional 3D CFD-based simulation with the adjusted turbulator spacing to, based on the additional 3D CFD-based simulation, determining the change in the DE; and repeating the further simulation loop.

An eighth embodiment, which is the system of the first embodiment, wherein the turbulator geometry of the turbulator is configured for a type of the wellbore cementing operation selected from the group consisting of a reverse cementing operation or a forward cementing operation.

A ninth embodiment, which is the system of the first embodiment, wherein the turbulator is selected from the group consisting of a rigid vane turbulator and a strap-on turbulator.

A tenth embodiment, which is a wellbore servicing method comprising: (I) preparing a work order associated with a wellbore cementing operation in a planning phase, the work order resulting from execution, on a processor communicatively coupled to a non-transitory memory, of operations comprising: (a) collecting an input of a user; (b) running an initial three-dimensional (3D) computational fluid dynamics (CFD)-based simulation of the cementing operation, the initial 3D CFD-based simulation outputting a 3D CFD result comprising a simulated annular placement of a cement within an annulus of a wellbore, the wellbore having a wellbore geometry, and a displacement efficiency (DE); (c) based on the input of the user, determining that the simulated annular placement of the cement from the initial 3D CFD-based simulation exhibits an insufficient DE within the annulus of the wellbore; (d) based on the input of the user, choosing a section of a casing of the wellbore, the section comprising a length of the casing from a first point to a second point; (e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation; (f) based on the input of the user, adjusting mechanical properties of the turbulator to maximize the DE of the cement within the section during the wellbore cementing operation, the mechanical properties including at least the size of the turbulator and the specifications of the turbulator; (g) creating the work order for a designed cementing operation that comprises adjusting a turbulator spacing along the casing of the wellbore to create an adjusted turbulator spacing, the adjusted turbulator spacing being one turbulator per joint; (h) performing an additional 3D CFD-based simulation of the cementing operation with the adjusted turbulator spacing, the additional 3D CFD-based displacement simulation updating and outputting the simulated annular placement of the cement within the annulus of the wellbore and the DE; (i) based on the additional 3D CFD-based simulation, determining a change in the DE; (j) based on the determined change in the DE, adjusting the work order based on a further simulation loop; and (k) after the further simulation loop ends, finalizing the work order for the designed cementing operation to yield a finalized work order comprising: the designated mechanical properties of each turbulator, a number of turbulators associated with the section of casing of the wellbore, a turbulator spacing associated with the section of the casing of the wellbore, and a pump schedule comprising a recipe/composition of the cement, a volume of the cement, a pumping rate, a pumping sequence, and an expected fluid profile, the expected fluid profile comprising expected fluid positions of the different wellbore fluids at an end of the wellbore cementing operation; (II) based on the finalized work order, performing the wellbore cementing operation comprising: (a) transporting the number of turbulators having the designated mechanical properties to a wellsite having the wellbore penetrating a subterranean formation; (b) installing the casing in the wellbore, wherein: an outer surface of the casing forms the annulus, the number of turbulators are coupled to the outer surface of the casing, and the number of turbulators are disposed and spaced within the annulus of the section of the casing of the wellbore in accordance with the turbulator spacing of the finalized work order; and (c) pumping, in accordance with the pumping schedule, the cement into the annulus, wherein the cement contacts the number of turbulators during the pumping, and the number of turbulators are configured to induce turbulence within the cement to at least reduce channeling of the cement within the annulus.

An eleventh embodiment, which is the method of the tenth embodiment, wherein at least one of the initial 3D CFD-based simulation or the additional 3D CFD-based simulation further comprises performing additional operations including: receiving, from the user, the wellbore geometry, the pump schedule, the turbulator spacing, and a turbulator geometry to be tested; storing, within the non-transitory memory, the wellbore geometry, the pump schedule, the turbulator spacing, and the turbulator geometry; estimating, using the turbulator geometry and the turbulator spacing, a swirl number, a swirl length and a corresponding boundary condition (BC) to be applied in a momentum solution, the BC represented as an equivalent casing rotation for the section of a casing where the turbulator is placed; solving prime velocities using previously generated turbulator effects; using the prime velocities, solving a pressure correction equation to obtain a pressure field; using the pressure field, correcting the prime velocities; solving a fluid concentration equation representing different wellbore fluids to determine different wellbore fluid positions in a simulated annulus at a given moment in time as the simulation proceeds; updating a plurality of fluid properties to create a plurality of updated fluid properties, the plurality of updated fluid properties being based at least in part on changes in the different wellbore fluid positions indicated by the pressure field; repeating, for the duration of a time loop having a plurality of iterations, the additional operations from solving the prime velocities to updating the plurality of fluid properties, each of the iterations of the time loop being configured to generate simulation results for a portion of the wellbore cementing operation, and the time loop being configured to simulate an entire duration of the wellbore cementing operation by combining the simulation results for all of the iterations of the time loop into the 3D CFD result, the 3D CFD result being based on the different wellbore fluid positions at a final iteration of the plurality of iterations of the time loop and comprising: the simulated annular placement of the cement within the annulus of the wellbore, and the DE; and storing the 3D CFD result.

A twelfth embodiment, which is the method of the eleventh embodiment, wherein the pump schedule is iteratively adjusted by the user to enhance the DE.

A thirteenth embodiment, which is the method of the tenth embodiment, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was not greater than the determined change in the DE, further comprising: further adjusting the adjusted turbulator spacing by doubling the number of turbulators per each section of the casing of the wellbore; repeating the operations from performing the additional 3D CFD-based simulation with the adjusted turbulator spacing to, based on the additional 3D CFD-based simulation, determining the change in the DE; and repeating the further simulation loop.

A fourteenth embodiment, which is the method of the tenth embodiment, wherein the further simulation loop comprises a determination that (1) the determined change in the DE resulting from the additional 3D CFD-based simulation is not an improvement over the insufficient DE from the initial 3D CFD-based simulation, and that (2) an immediately preceding DE from an immediately preceding 3D CFD-based simulation was greater than the determined change in the DE, further comprising halting the further simulation loop.

A fifteenth embodiment, which is the method of the tenth embodiment, wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was not greater than the determined change in the DE, further comprising halting the further simulation loop.

A sixteenth embodiment, which is the method of the tenth embodiment wherein the further simulation loop comprises a determination that (1) the determined change in the DE resulting from the additional 3D CFD-based simulation is an improvement over the insufficient DE from the initial 3D CFD-based simulation, and that (2) an immediately preceding DE from an immediately preceding 3D CFD-based simulation was greater than the determined change in the DE, further comprising: further adjusting the adjusted turbulator spacing by halving a number of turbulators per joint; repeating the operations from performing the additional 3D CFD-based simulation with the adjusted turbulator spacing to, based on the additional 3D CFD-based simulation, determining the change in the DE; and repeating the further simulation loop.

A seventeenth embodiment, which is the method of the tenth embodiment, wherein the turbulator geometry of the turbulator is configured for a type of the wellbore cementing operation selected from the group consisting of a reverse cementing operation or a forward cementing operation.

An eighteenth embodiment, which is the method of the tenth embodiment, wherein the turbulator is selected from the group consisting of a rigid vane turbulator and a strap-on turbulator.

A nineteenth embodiment, which is a system for using a three-dimensional (3D) computational fluid dynamics (CFD)-based model to prepare a finalized work order associated with a wellbore cementing operation in a planning phase and to schedule the wellbore cementing operation based on the finalized work order, the system comprising: a data acquisition subsystem communicatively coupled to a data storage subsystem, a user interface subsystem, a work order generator, and a wellbore cementing operation scheduler, the work order generator being further communicatively coupled to the wellbore cementing operation scheduler; the work order generator comprising a first processor and a first non-transitory memory and configured to perform a first set of operations comprising: (a) collecting by the data acquisition subsystem via the user interface subsystem an input from a user and storing the input in a data storage subsystem; (b) based on the input of the user, running an initial three-dimensional (3D) computational fluid dynamics (CFD)-based simulation of the cementing operation, the initial 3D CFD-based simulation outputting a 3D CFD result comprising a simulated annular placement of a cement within an annulus of a wellbore, the wellbore having a wellbore geometry, and a displacement efficiency (DE); (c) based on the input of the user, determining that the simulated annular placement of the cement from the initial 3D CFD-based simulation exhibits an insufficient DE within the annulus of the wellbore; (d) based on the input of the user, choosing a section of a casing of the wellbore, the section comprising a length of the casing from a first point to a second point; (e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation; (f) based on the input of the user, adjusting mechanical properties of the turbulator to maximize the DE of the cement within the section during the wellbore cementing operation, the mechanical properties including at least the size of the turbulator and the specifications of the turbulator; (g) creating the work order for a designed cementing operation that comprises adjusting a turbulator spacing along the casing of the wellbore to create an adjusted turbulator spacing, the adjusted turbulator spacing being one turbulator per joint; (h) performing an additional 3D CFD-based simulation of the cementing operation with the adjusted turbulator spacing, the additional 3D CFD-based displacement simulation updating and outputting the simulated annular placement of the cement within the annulus of the wellbore and the DE; (i) based on the additional 3D CFD-based simulation, determining a change in the DE; (j) based on the determined change in the DE, adjusting the work order based on a further simulation loop; and (k) after the further simulation loop ends, finalizing the work order for the designed cementing operation to yield the finalized work order comprising: the designated mechanical properties of each turbulator, a number of turbulators associated with the section of casing of the wellbore, a turbulator spacing associated with the section of the casing of the wellbore, and a pump schedule comprising a recipe of the cement, a volume of the cement, a pumping rate, a pumping sequence, and an expected fluid profile, the expected fluid profile comprising expected fluid positions of the different wellbore fluids at an end of the wellbore cementing operation; a cementing operation scheduler comprising a second processor and a second non-transitory memory and configured to perform a second set of operations comprising: receiving the finalized work order from the work order generator; and generating a cementing operation schedule based on the finalized work order, the cementing operation schedule configured to at least reduce channeling of the cement within the annulus during the wellbore cementing operation.

A twentieth embodiment, which is the system of the nineteenth embodiment, wherein at least one of the initial 3D CFD-based simulation or the additional 3D CFD-based simulation further comprises performing additional operations including: receiving, from the user, the wellbore geometry, the pump schedule, the turbulator spacing, and a turbulator geometry to be tested; storing, within the non-transitory memory, the wellbore geometry, the pump schedule, the turbulator spacing, and the turbulator geometry; estimating, using the turbulator geometry and the turbulator spacing, a swirl number, a swirl length and a corresponding boundary condition (BC) to be applied in a momentum solution, the BC represented as an equivalent casing rotation for the section of a casing where the turbulator is placed; solving prime velocities using previously generated turbulator effects; using the prime velocities, solving a pressure correction equation to obtain a pressure field; using the pressure field, correct the prime velocities; solving a fluid concentration equation representing different wellbore fluids to determine different wellbore fluid positions in a simulated annulus at a given moment in time as the simulation proceeds; updating a plurality of fluid properties to create a plurality of updated fluid properties, the plurality of updated fluid properties being based at least in part on changes in the different wellbore fluid positions indicated by the pressure field; repeating, for the duration of a time loop having a plurality of iterations, the additional operations from solving the prime velocities to updating the plurality of fluid properties, each of the iterations of the time loop being configured to generate simulation results for a portion of the wellbore cementing operation, and the time loop being configured to simulate an entire duration of the wellbore cementing operation by combining the simulation results for all of the iterations of the time loop into the 3D CFD result, the 3D CFD result being based on the different wellbore fluid positions at a final iteration of the plurality of iterations of the time loop and comprising: the simulated annular placement of the cement within the annulus of the wellbore, and the DE; and storing the 3D CFD result.

A twenty-first embodiment, which is any of the first through twentieth embodiments, wherein the work order further comprises a turbulator parts list and a pumping schedule.

A twenty-second embodiment, which is any of the first through the twenty-first embodiments, wherein the 3D CFD-based simulation is replaced with a 2D CFD-based simulation or other type of conventional CFD simulation.

A twenty-third embodiment, which is any of the first through the twenty-second embodiments, wherein the term “3D CFD-based simulation” and the like are replaced with “CFD-based simulation” and the like to otherwise include any known or conventional type of CFD simulation, including but not limited to 3D or 2D.

In the context of this disclosure, “A or B,” shall mean “A or B or both.” Additionally, any list of elements (e.g., “A, B, C, . . . , or N”) shall mean one or more of each element in the list (e.g., one or more of A, B, C, . . . . N).

In addition to and notwithstanding the foregoing, “displacement” includes but is not limited to displacing drilling mud and other materials out of a casing or an annulus by pumping other fluids like flushes, spacer fluids and cements into a casing or an annulus. The disclosed systems and methods use a three-dimensional computational fluid dynamics-based model to model at least the transient, incompressible, multi-species, non-Newtonian nature of the flow through the casing and the annulus.

In some embodiments, “work order,” as defined and used herein, and “design of service” or “turbulator parts list” can be used interchangeably.

When planning a well cementing job, certain manipulable factors are known to impact cement DE when turbulators are not present. These include but are not limited to non-centralizer induced casing centralization, deploying mechanical aids impacting casing movement, accounting for the fluid density hierarchy, accounting for the fluid rheology hierarchy, adjusting the cement pump rate, deploying spacers, and mud conditioning. In at least some cementing job design cases where, despite optimizing the above factors (or, in the alternative, being unable to optimize at least one of the above factors due to real-world constraints), the desired DE has not been achieved, turbulators and the disclosed systems and methods herein are usable to improve the DE at the design stage.

For example, and as noted elsewhere herein, turbulators are particularly performant versus other means of improving DE for reverse cementing (also sometimes called “reverse circulation”) operations. Reverse cementing must account for inverse density hierarchies (e.g., cement being heavier than the other fluids involved, the cement will sink through those other, lighter fluids during the cementing operation). Lighter fluids include those that are less dense, including but not limited to certain drilling muds. Where the mud has lower density than the cement, without any mitigation the cement will tend to channel through the mud without covering the circumference of the annulus, creating channeling. Stable cement displacements using reverse cementing with satisfactory DE are achievable by employing turbulators, which are configurable to improve DE while in the presence of inverse density hierarchies. Often in reverse cementing operations, properties such as fluid density, velocity, etc. cannot be sufficiently directly manipulated. The use of turbulators as explained elsewhere herein enables compensating for the inability to directly manipulate these properties. Other contemporary and traditional types of wellbore centralizers, lacking the properties of turbulators described herein, are not commercially practicable for such reverse cementing operations.

In embodiments herein, the 3D CFD-based simulation is configurable various portions of an annulus, wellbore, casing, or any combination thereof. Example simulations include but are not limited to a single joint, multiple joints, an arbitrary depth, a range of depths, etc. In some embodiments, how much of a casing string or wellbore is simulated at once is constrained only by the available computing power or computing resources of the computer system running the simulation (e.g., the computer system 2100, herein). In such embodiments, where sufficient computing power or computing resources are available to, for example, simulate an entire wellbore, there are no other practical limitations on how much of the wellbore or casing string is subject to simulation using the systems and methods herein.

In some embodiments herein, simulations using the systems and methods disclosed reveal for that for certain wellbores and casing strings, the ideal turbulator spacing is twenty feet apart or less. In some such embodiments, this ideal spacing indicates that only one or two turbulators is placed per joint, as standard wellbore casing joints are forty feet long. Where only one or two turbulators is placed per joint, the 3D CFD-based simulation determines how far apart the turbulators should be, accounting for cases where the optimal DE is achieved when at least one joint has no turbulators while other joints do have turbulators (e.g., turbulators spaced apart by twenty feet, forty feet, sixty feet, eighty feet, etc.). In the same vein, using the systems and methods herein, depending on the cementing operation being simulated the number of turbulators per joint changes over the length of the wellbore. Further, embodiments use the systems and methods disclosed herein to simulate not only a single joint of casing string, or even multiple joints of casing string, but the entire casing string over the entire wellbore to measure the impact of turbulator placement on DE across the entire wellbore. In some such embodiments, the optimal number of turbulators per joint according to the 3D CFD-based simulation of the systems and methods herein varies with depth—for example, more turbulators are needed to achieve the same advantageous effect on DE as depth increases.

In any of these cases, or indeed in any case involving simulating the use of turbulators in wellbore cementing operations, in embodiments herein 3D CFD-based simulations are conducted to determine the fewest number of turbulators to place to achieve a desired displacement efficiency without undesired side effects. One such side effect is excess drag or friction—each turbulator placed introduces drag on the cement flowing into the annulus during a cementing operation. An excess of turbulators thus translates into unnecessary drag, which slows the cementing operation, increases equipment wear and time/labor costs, and introduces other such related negative consequences.

In some embodiments, at least one of the process flow 800, the process flow 900, the method 1800, or the method 1900 is usable to simulate a cementing job associated with either an offshore wellbore, or an on-land wellbore. In some such embodiments, the process flow 800, the process flow 900, the method 1800, or the method 1900 is performed at least two to three years before a scheduled offshore wellbore cementing operation. In other such embodiments, the process flow 800, the process flow 900, the method 1800, or the method 1900 is performed at least one week before a scheduled cementing on-land wellbore cementing operation. In yet other such embodiments, the process flow 800, the process flow 900, the method 1800, or the method 1900 is performed at least one month before a scheduled cementing on-land wellbore cementing operation.

Embodiments of methods and processes herein include the operation of “solving a fluid concentration equation representing different wellbore fluids to determine different wellbore fluid positions.” In some such embodiments, the fluid concentration equation is the advection diffusion equation associated with passive transport. One expression of the advection diffusion equation, presented in Transport Phenomena, Second Edition, by Bird, Stewart, Lightfoot at page 913 is provided below, and has the meaning and usage described in that reference. In other such embodiments, alternative fluid concentration equation(s) having output(s) usable with the systems, processes, and methods disclosed herein are usable.

### Advection Diffusion Equation:

$$Mass ( for binary mixtures of A and B with constant ρ {AB}_{} ) : \qquad ( § B \text{.11} )$$

$$ρ \frac{D {ω}_{A}}{Dt} = ρ ( \frac{\partial {ω}_{A}}{\partial t} + ( v \cdot ∇ {ω}_{A} ) ) = ρ {A B}_{} {∇}^{2} {ω}_{A} + {r}_{A}$$

In embodiments herein, a turbulator is a class of solid-body centralizer that is rugged and, while being usable in any wellbore, is particularly well suited for deviated wellbores. In some embodiments herein, turbulators are constructed using cast aluminum or steel materials. While solid-body centralizers are sometimes less effective than bow spring centralizers when the diameter of the centralizer is less than the wellbore diameter of the wellbore, solid-body centralizers (e.g., turbulators) have the advantage of durability and superior performance in deviated wellbores.

In some embodiments, turbulator blade exit angles and entrance angles are each between zero degrees and ninety degrees. In such embodiments, optimal entrance angles and exit angles are between twenty-five degrees and sixty-degrees (or an equivalent value measured in radians or any other compatible unit of measure for blade angle). In some such embodiments, a ninety degree angle indicates a total obstruction that renders the turbulator inoperative; in some such embodiments a warning for a user is triggered in a user interface of the simulator. In some embodiments, entrance angles and exit angles are both available on turbulator data sets. However, in some other embodiments, a turbulator data sheet includes only an entrance angle or only an exit angle. In such embodiments, where only one of the entrance angle or exit angle are provided, the missing angle shall be set equal to the present angle for purposes of the calculations and simulations described herein.

Several embodiments herein have accompanying figures visually representing the impact on simulated turbulator placement on cement channeling. In interpreting these figures, turbulator placement efficacy is denoted not by creation of a smooth, flat cement/annulus boundary (though in some embodiments such cement placement would be advantageous), but instead the reduction of cement peaks and valleys.

In such embodiments, real-world turbulators have a blade length that is a positive integer or positive floating point number. In some embodiments, if a user does not indicate a blade length, the blade length is calculated automatically based at least one on the entrance angle, the exit angle and the height of the turbulator. In other embodiments, if the user enters a blade length that is either below or above an allowed range of blade length values, this user input is overridden by such an automated calculation.

While embodiments of the invention have been shown and described, modifications thereof can be made by one skilled in the art without departing from the spirit and teachings of the invention. The embodiments described herein are exemplary only, and are not intended to be limiting. Many variations and modifications of the invention disclosed herein are possible and are within the scope of the invention. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, Rl, and an upper limit, Ru, is disclosed, any number falling within the range is specifically disclosed. In particular, the following numbers within the range are specifically disclosed: R=R1+k*(Ru−Rl), wherein k is a variable ranging from 1 percent to 100 percent with a 1 percent increment, i.e., k is 1 percent, 2 percent, 3 percent, 4 percent, 5 percent, . . . 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of the term “optionally” with respect to any element of a claim is intended to mean that the subject element is required, or alternatively, is not required. Both alternatives are intended to be within the scope of the claim. Use of broader terms such as comprises, includes, having, etc. should be understood to provide support for narrower terms such as consisting of, consisting essentially of, comprised substantially of, etc.

Accordingly, the scope of protection is not limited by the description set out above but is only limited by the claims which follow, that scope including all equivalents of the subject matter of the claims. Each and every claim is incorporated into the specification as an embodiment of the present invention. Thus, the claims are a further description and are an addition to the embodiments of the present invention. The discussion of a reference in the Detailed Description of the Embodiments is not an admission that it is prior art to the present invention, especially any reference that may have a publication date after the priority date of this application. The disclosures of all patents, patent applications, and publications cited herein are hereby incorporated by reference, to the extent that they provide exemplary, procedural or other details supplementary to those set forth herein.

What is claimed is:

1. A wellbore servicing method comprising:
(I) preparing a turbulator parts list associated with a wellbore cementing operation in a planning phase, the turbulator parts list resulting from execution, on a processor communicatively coupled to a non-transitory memory, of operations comprising:
(a) collecting an input of a user;
(b) running an initial computational fluid dynamics (CFD)-based simulation of the cementing operation, the initial CFD-based simulation outputting a CFD result comprising a simulated annular placement of a cement within an annulus of a wellbore, the wellbore having a wellbore geometry, and a displacement efficiency (DE);
(c) based on the input of the user, determining that the simulated annular placement of the cement from the initial CFD-based simulation exhibits an insufficient DE within the annulus of the wellbore;
(d) based on the input of the user, choosing a section of a casing of the wellbore, the section comprising a length of the casing from a first point to a second point;
(e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation;
(f) based on the input of the user, adjusting mechanical properties of the turbulator to maximize the DE of the cement within the section during the wellbore cementing operation, the mechanical properties including at least the size of the turbulator and the specifications of the turbulator;
(g) creating the turbulator parts list for a designed cementing operation that comprises adjusting a turbulator spacing along the casing of the wellbore to create an adjusted turbulator spacing, the adjusted turbulator spacing being one turbulator per joint;
(h) performing an additional CFD-based simulation of the cementing operation with the adjusted turbulator spacing, the additional CFD-based displacement simulation updating and outputting the simulated annular placement of the cement within the annulus of the wellbore and the DE;
(i) based on the additional CFD-based simulation, determining a change in the DE;
(j) based on the determined change in the DE, adjusting the turbulator parts list based on a further simulation loop; and
(k) after the further simulation loop ends, finalizing the turbulator parts list for the designed cementing operation to yield a finalized turbulator parts list comprising:
the designated mechanical properties of each turbulator,
a number of turbulators associated with the section of casing of the wellbore, and
a turbulator spacing associated with the section of the casing of the wellbore;
(II) based on the finalized turbulator parts list, performing the wellbore cementing operation comprising:
(a) transporting the number of turbulators having the designated mechanical properties to a wellsite having the wellbore penetrating a subterranean formation;
(b) installing the casing in the wellbore, wherein:
an outer surface of the casing forms the annulus,
the number of turbulators are coupled to the outer surface of the casing, and
the number of turbulators are disposed and spaced within the annulus of the section of the casing of the wellbore in accordance with the turbulator spacing of the finalized turbulator parts list; and
(c) pumping, in accordance with a pumping schedule, the cement into the annulus, wherein the cement contacts the number of turbulators during the pumping, and the number of turbulators are configured to induce turbulence within the cement to at least reduce channeling of the cement within the annulus.

2. The wellbore servicing method of claim 1, wherein at least one of the initial CFD-based simulation or the additional CFD-based simulation further comprises performing additional operations including:
receiving, from the user, the wellbore geometry, the pump schedule, the turbulator spacing, and a turbulator geometry to be tested;
storing, within the non-transitory memory, the wellbore geometry, the pump schedule, the turbulator spacing, and the turbulator geometry;
estimating, using the turbulator geometry and the turbulator spacing, a swirl number, a swirl length and a corresponding boundary condition (BC) to be applied in a momentum solution, the BC represented as an equivalent casing rotation for the section of a casing where the turbulator is placed;
solving prime velocities using previously generated turbulator effects;
using the prime velocities, solving a pressure correction equation to obtain a pressure field;
using the pressure field, correct the prime velocities;
solving a fluid concentration equation representing different wellbore fluids to determine different wellbore fluid positions in a simulated annulus at a given moment in time as the simulation proceeds;
updating a plurality of fluid properties to create a plurality of updated fluid properties, the plurality of updated fluid properties being based at least in part on changes in the different wellbore fluid positions indicated by the pressure field;
repeating, for the duration of a time loop having a plurality of iterations, the additional operations from solving the prime velocities to updating the plurality of fluid properties,
each of the iterations of the time loop being configured to generate simulation results for a portion of the wellbore cementing operation, and
the time loop being configured to simulate an entire duration of the wellbore cementing operation by combining the simulation results for all of the iterations of the time loop into the CFD result, the CFD result being based on the different wellbore fluid positions at a final iteration of the plurality of iterations of the time loop and comprising: the simulated annular placement of the cement within the annulus of the wellbore, and the DE; and
storing the CFD result.

3. The wellbore servicing method of claim 2, wherein the pump schedule is iteratively adjusted by the user to enhance the DE.

4. The wellbore servicing method of claim 1, wherein the further simulation loop comprises a determination that (1) the determined change in the DE resulting from the additional CFD-based simulation is not an improvement over the insufficient DE from the initial CFD-based simulation, and that (2) an immediately preceding DE from an immediately preceding CFD-based simulation was not greater than the determined change in the DE,
further comprising:
further adjusting the adjusted turbulator spacing by doubling the number of turbulators per each section of the casing of the wellbore;
repeating the operations from performing the additional CFD-based simulation with the adjusted turbulator spacing to, based on the additional CFD-based simulation, determining the change in the DE; and
repeating the further simulation loop.

5. The wellbore servicing method of claim 1, wherein the further simulation loop comprises a determination that (1) the determined change in the DE resulting from the additional CFD-based simulation is not an improvement over the insufficient DE from the initial CFD-based simulation, and that (2) an immediately preceding DE from an immediately preceding CFD-based simulation was greater than the determined change in the DE,
further comprising halting the further simulation loop.

6. The wellbore servicing method of claim 1, wherein the further simulation loop comprises a determination that (1) the determined change in the DE resulting from the additional CFD-based simulation is an improvement over the insufficient DE from the initial CFD-based simulation, and that (2) an immediately preceding DE from an immediately preceding CFD-based simulation was not greater than the determined change in the DE,
further comprising halting the further simulation loop.

7. The wellbore servicing method of claim 1, wherein the further simulation loop comprises a determination that (1) the determined change in the DE resulting from the additional CFD-based simulation is an improvement over the insufficient DE from the initial CFD-based simulation, and that (2) an immediately preceding DE from an immediately preceding CFD-based simulation was greater than the determined change in the DE,
further comprising:
further adjusting the adjusted turbulator spacing by halving a number of turbulators per joint;
repeating the operations from performing the additional CFD-based simulation with the adjusted turbulator spacing to, based on the additional CFD-based simulation, determining the change in the DE; and
repeating the further simulation loop.

8. The wellbore servicing method of claim 1, wherein the turbulator geometry of the turbulator is configured for a type of the wellbore cementing operation selected from the group consisting of a reverse cementing operation or a forward cementing operation.

9. The wellbore servicing method of claim 1, wherein the turbulator is selected from the group consisting of a rigid vane turbulator, a strap-on turbulator, and combinations thereof.

10. A system for performing a wellbore cementing operation on a wellbore at a wellsite, comprising:
a data acquisition subsystem communicatively coupled to a data storage subsystem, a user interface subsystem, and a turbulator parts list generator, the turbulator parts list generator having a processor communicatively coupled to a non-transitory memory;
a finalized turbulator parts list for a designed cementing operation generated by the turbulator parts list generator and stored in the non-transitory memory,
wherein the turbulator parts list generator is configured to generate the finalized turbulator parts list based on preparing a turbulator parts list associated with the wellbore cementing operation in a planning phase by executing operations comprising:
(a) collecting by the data acquisition subsystem via the user interface subsystem an input from a user and storing the input in the data storage subsystem;
(b) based on the input of the user, running an initial computational fluid dynamics (CFD)-based simulation of the cementing operation, the initial CFD-based simulation outputting a CFD result comprising a simulated annular placement of a cement within an annulus of a wellbore, the wellbore having a wellbore geometry and a displacement efficiency (DE);
(c) based on the input of the user, determining that the simulated annular placement of the cement from the initial CFD-based simulation exhibits an insufficient DE within the annulus of the wellbore;
(d) based on the input of the user, choosing the section of the casing of the wellbore, the section comprising a length of the casing from a first point to a second point;
(e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation;
(f) based on the input of the user, adjusting mechanical properties of the turbulator to maximize the DE of the cement within the section during the wellbore cementing operation, the mechanical properties including at least the size of the turbulator and the specifications of the turbulator;
(g) creating the turbulator parts list for a designed cementing operation that comprises adjusting a turbulator spacing along the casing of the wellbore to create an adjusted turbulator spacing, the adjusted turbulator spacing being one turbulator per joint;
(h) performing an additional CFD-based simulation of the cementing operation with the adjusted turbulator spacing, the additional CFD-based displacement simulation updating and outputting the simulated annular placement of the cement within the annulus of the wellbore and the DE;
(i) based on the additional CFD-based simulation, determining a change in the DE;
(j) based on the determined change in the DE, adjusting the turbulator parts list based on a further simulation loop; and
(k) after the further simulation loop ends, finalizing the turbulator parts list for the designed cementing operation to yield the finalized turbulator parts list comprising:
the designated mechanical properties of each turbulator,
the number of turbulators associated with the section of the casing of the wellbore, and
the turbulator spacing associated with the section of the casing of the wellbore.

11. The system of claim 10, further comprising:
a transport system configured to transport a number of turbulators identified in the finalized turbulator parts list to the wellsite having the wellbore penetrating a subterranean formation;
a casing installation subsystem configured to install the casing in the wellbore, wherein:
an outer surface of the casing forms the annulus,
the number of turbulators are coupled to the outer surface of the casing, and
the number of turbulators are disposed and spaced within the annulus of a section of the casing of the wellbore in accordance with the turbulator spacing of the finalized turbulator parts list; and
a pumping subsystem configured to pump, in accordance with a pumping schedule associated with the finalized turbulator parts list, cement into the annulus, wherein the cement contacts the number of turbulators during the pumping, and the number of turbulators are configured to induce turbulence within the cement to at least reduce channeling of the cement within the annulus.

12. The system of claim 10, wherein at least one of the initial CFD-based simulation or the additional CFD-based simulation further comprises performing additional operations including:
receiving, from the user, the wellbore geometry, the pump schedule, the turbulator spacing, and a turbulator geometry to be tested;
storing, within the non-transitory memory, the wellbore geometry, the pump schedule, the turbulator spacing, and the turbulator geometry;
estimating, using the turbulator geometry and the turbulator spacing, a swirl number, a swirl length and a corresponding boundary condition (BC) to be applied in a momentum solution, the BC represented as an equivalent casing rotation for the section of the casing where the turbulator is placed;
solving prime velocities using previously generated turbulator effects;
using the prime velocities, solving a pressure correction equation to obtain a pressure field;
using the pressure field, correcting the prime velocities;
solving a fluid concentration equation representing different wellbore fluids to determine different wellbore fluid positions in a simulated annulus at a given moment in time as the simulation proceeds;
updating a plurality of fluid properties to create a plurality of updated fluid properties, the plurality of updated fluid properties being based at least in part on changes in the different wellbore fluid positions indicated by the pressure field;
repeating, for the duration of a time loop having a plurality of iterations, the additional operations from solving the prime velocities to updating the plurality of fluid properties,
each of the iterations of the time loop being configured to generate simulation results for a portion of the wellbore cementing operation, and
the time loop being configured to simulate an entire duration of the wellbore cementing operation by combining the simulation results for all of the iterations of the time loop into the CFD result, the CFD result being based on the different wellbore fluid positions at a final iteration of the plurality of iterations of the time loop and comprising: the simulated annular placement of the cement within the annulus of the wellbore, and the DE; and
storing the CFD result.

13. The system of claim 10, wherein the further simulation loop comprises a determination that (1) the determined change in the DE resulting from the additional CFD-based simulation is not an improvement over the insufficient DE from the initial CFD-based simulation, and that (2) an immediately preceding DE from an immediately preceding CFD-based simulation was not greater than the determined change in the DE,
operations performed by the turbulator parts list generator further comprise:
further adjusting the adjusted turbulator spacing by doubling the number of turbulators per each section of the casing of the wellbore;
repeating the operations from performing the additional CFD-based simulation with the adjusted turbulator spacing to, based on the additional CFD-based simulation, determining the change in the DE; and
repeating the further simulation loop.

14. The system of claim 10, wherein the further simulation loop comprises a determination that (1) the determined change in the DE resulting from the additional CFD-based simulation is not an improvement over the insufficient DE from the initial CFD-based simulation, and that (2) an immediately preceding DE from an immediately preceding CFD-based simulation was greater than the determined change in the DE,
operations performed by the turbulator parts list generator further comprise halting the further simulation loop.

15. The system of claim 10, wherein the further simulation loop comprises a determination that (1) the determined change in the DE resulting from the additional CFD-based simulation is an improvement over the insufficient DE from the initial CFD-based simulation, and that (2) an immediately preceding DE from an immediately preceding CFD-based simulation was not greater than the determined change in the DE,
operations performed by the turbulator parts list generator further comprise halting the further simulation loop.

16. The system of claim 10, wherein the further simulation loop comprises a determination that (1) the determined change in the DE resulting from the additional CFD-based simulation is an improvement over the insufficient DE from the initial CFD-based simulation, and that (2) an immediately preceding DE from an immediately preceding CFD-based simulation was greater than the determined change in the DE,
operations performed by the turbulator parts list generator further comprise:
further adjusting the adjusted turbulator spacing by halving a number of turbulators per joint;
repeating the operations from performing the additional CFD-based simulation with the adjusted turbulator spacing to, based on the additional CFD-based simulation, determining the change in the DE; and
repeating the further simulation loop.

17. The system of claim 10, wherein the turbulator geometry of the turbulator is configured for a type of the wellbore cementing operation selected from the group consisting of a reverse cementing operation or a forward cementing operation.

18. The system of claim 10, wherein the turbulator is selected from the group consisting of a rigid vane turbulator, a strap-on turbulator, and combinations thereof.

19. A system for using a three-dimensional (3D) computational fluid dynamics (CFD)-based model to prepare a finalized work order associated with a wellbore cementing operation in a planning phase and to schedule the wellbore cementing operation based on the finalized work order, the system comprising:
a data acquisition subsystem communicatively coupled to a data storage subsystem, a user interface subsystem, a work order generator, and a wellbore cementing operation scheduler, the work order generator being further communicatively coupled to the wellbore cementing operation scheduler;
the work order generator comprising a first processor and a first non-transitory memory and configured to perform a first set of operations comprising:
(a) collecting by the data acquisition subsystem via the user interface subsystem an input from a user and storing the input in the data storage subsystem;
(b) based on the input of the user, running an initial three-dimensional (3D) computational fluid dynamics (CFD)-based simulation of the cementing operation, the initial 3D CFD-based simulation outputting a 3D CFD result comprising a simulated annular placement of a cement within an annulus of a wellbore, the wellbore having a wellbore geometry, and a displacement efficiency (DE);
(c) based on the input of the user, determining that the simulated annular placement of the cement from the initial 3D CFD-based simulation exhibits an insufficient DE within the annulus of the wellbore;
(d) based on the input of the user, choosing a section of a casing of the wellbore, the section comprising a length of the casing from a first point to a second point;
(e) simulating mechanically coupling a turbulator to the section of the casing of the wellbore prior to the installation of the casing within the wellbore, the turbulator configured to adjust the DE of the cement within the annulus and proximate to the section of the casing during the wellbore cementing operation;
(f) based on the input of the user, adjusting mechanical properties of the turbulator to maximize the DE of the cement within the section during the wellbore cementing operation, the mechanical properties including at least the size of the turbulator and the specifications of the turbulator;
(g) creating the work order for a designed cementing operation that comprises adjusting a turbulator spacing along the casing of the wellbore to create an adjusted turbulator spacing, the adjusted turbulator spacing being one turbulator per joint;
(h) performing an additional 3D CFD-based simulation of the cementing operation with the adjusted turbulator spacing, the additional 3D CFD-based displacement simulation updating and outputting the simulated annular placement of the cement within the annulus of the wellbore and the DE;
(i) based on the additional 3D CFD-based simulation, determining a change in the DE;
(j) based on the determined change in the DE, adjusting the work order based on a further simulation loop; and
(k) after the further simulation loop ends, finalizing the work order for the designed cementing operation to yield the finalized work order comprising:
the designated mechanical properties of each turbulator,
a number of turbulators associated with the section of casing of the wellbore,
a turbulator spacing associated with the section of the casing of the wellbore, and
a pump schedule comprising a composition of the cement, a volume of the cement, a pumping rate, a pumping sequence, and an expected fluid profile, the expected fluid profile comprising expected fluid positions of the different wellbore fluids at an end of the wellbore cementing operation;
the cementing operation scheduler comprising a second processor and a second non-transitory memory and configured to perform a second set of operations comprising:
receiving the finalized work order from the work order generator; and
generating a cementing operation schedule based on the finalized work order, the cementing operation schedule configured to at least reduce channeling of the cement within the annulus during the wellbore cementing operation.

20. The system of claim 19, wherein at least one of the initial 3D CFD-based simulation or the additional 3D CFD-based simulation further comprises performing additional operations including:
receiving, from the user, the wellbore geometry, the pump schedule, the turbulator spacing, and a turbulator geometry to be tested;
storing, within the first non-transitory memory, the wellbore geometry, the pump schedule, the turbulator spacing, and the turbulator geometry;
estimating, using the turbulator geometry and the turbulator spacing, a swirl number, a swirl length and a corresponding boundary condition (BC) to be applied in a momentum solution, the BC represented as an equivalent casing rotation for the section of a casing where the turbulator is placed;
solving prime velocities using previously generated turbulator effects;
using the prime velocities, solving a pressure correction equation to obtain a pressure field;
using the pressure field, correcting the prime velocities;
solving a fluid concentration equation representing different wellbore fluids to determine different wellbore fluid positions in a simulated annulus at a given moment in time as the simulation proceeds;
updating a plurality of fluid properties to create a plurality of updated fluid properties, the plurality of updated fluid properties being based at least in part on changes in the different wellbore fluid positions indicated by the pressure field;
repeating, for the duration of a time loop having a plurality of iterations, the additional operations from solving the prime velocities to updating the plurality of fluid properties,
each of the iterations of the time loop being configured to generate simulation results for a portion of the wellbore cementing operation, and
the time loop being configured to simulate an entire duration of the wellbore cementing operation by combining the simulation results for all of the iterations of the time loop into the 3D CFD result, the 3D CFD result being based on the different wellbore fluid positions at a final iteration of the plurality of iterations of the time loop and comprising: the simulated annular placement of the cement within the annulus of the wellbore, and the DE; and
storing the 3D CFD result.

21. The method of claim 1 wherein the computational fluid dynamics (CFD)-based simulation is a three-dimensional (3D) computational fluid dynamics (CFD)-based simulation.
